(19) United States
(12) Patent Application Publication
(10) Pub. No.: US 2026/0032995 A1
(43) Pub. Date: Jan. 29, 2026

(54) SEMICONDUCTOR DEVICES

(71) Applicant: Samsung Electronics Co., Ltd., Suwon-si (KR)

(72) Inventors: SO RA YOU, Suwon-si (KR); YOUNG HAN KIM, Suwon-si (KR); YOO LIM AHN, Suwon-si (KR); MIN CHAN GWAK, Suwon-si (KR)

(21) Appl. No.: 19/058,330

(22) Filed: Feb. 20, 2025

(30) Foreign Application Priority Data
Jul. 24, 2024 (KR) 10-2024-0097904

(51) Int. Cl. H10D 84/83; H10D 30/00; H10D 30/01; H10D 30/43; H10D 62/10; H10D 62/13; H10D 64/23; H10D 84/01

(52) U.S. Cl. CPC H10D 84/832; H10D 30/43; H10D 30/502; H10D 62/102; H10D 62/121; H10D 62/151; H10D 64/256; H10D 84/8312; H10D 30/014; H10D 30/0191; H10D 84/0153

(57) ABSTRACT

A semiconductor device includes a lower interlayer insulating layer and an active pattern thereon, wherein the active pattern extends in a first horizontal direction and is spaced apart from an upper surface of the lower interlayer insulating layer in a vertical direction; first nanosheets on the active pattern; second nanosheets spaced apart from the first nanosheets in the first horizontal direction on the active pattern; a first gate electrode extending in a second horizontal direction and extending around the first plurality of nanosheets; a capping layer on the first gate electrode; and an active cut on the lower interlayer insulating layer, wherein the active cut is spaced apart from the first gate electrode in the first horizontal direction, and an uppermost surface of the active cut is farther than an upper surface of the capping layer from the upper surface of the lower interlayer insulating layer.

### CROSS-REFERENCE TO RELATED APPLICATIONS

This application claims priority from Korean Patent Application No. 10-2024-0097904 filed on Jul. 24, 2024 in the Korean Intellectual Property Office, and all the benefits accruing therefrom under 35 U.S.C. 119, the contents of which in its entirety are herein incorporated by reference.

### BACKGROUND OF THE INVENTION

The present disclosure relates to electronic devices, such as semiconductor devices. Specifically, the present disclosure may relate to semiconductor devices including an MBCFET™ (Multi-Bridge Channel Field Effect Transistor).

As one of scaling technologies for increasing density of an integrated circuit device, a multi-gate transistor in which a silicon body having a fin shape or a nanowire shape is formed on a substrate and a gate is formed on a surface of the silicon body has been proposed.

Since such a multi-gate transistor utilizes a three-dimensional channel, (further) scaling may be possible. Further, even if a gate length of the multi-gate transistor is not increased, the current control capability may be improved. Furthermore, a SCE (short channel effect) in which potential of a channel region is influenced by a drain voltage may be effectively suppressed.

### SUMMARY OF THE INVENTION

Aspects of the present disclosure may provide a semiconductor device in which the process difficulty is reduced by forming an active cut from a lower part of an active pattern. In addition, aspects of the present disclosure may provide a semiconductor device in which the reliability of the active cut is improved by forming the active cut to penetrate a capping layer.

According to some embodiments of the present disclosure, there is provided a semiconductor device, comprising a lower interlayer insulating layer; an active pattern on an upper surface of the lower interlayer insulating layer, wherein the active pattern extends in a first horizontal direction that is parallel with the upper surface of the lower interlayer insulating layer, and wherein the active pattern is spaced apart from the upper surface of the lower interlayer insulating layer in a vertical direction that is perpendicular to the upper surface of the lower interlayer insulating layer; a first plurality of nanosheets on the active pattern, wherein first nanosheets of the first plurality of nanosheets are spaced apart from each other in the vertical direction; a second plurality of nanosheets on the active pattern, wherein second nanosheets of the second plurality of nanosheets are spaced apart from each other in the vertical direction, and wherein the second plurality of nanosheets is spaced apart from the first plurality of nanosheets in the first horizontal direction; a first gate electrode on the active pattern, wherein the first gate electrode extends in a second horizontal direction that is parallel with the upper surface of the lower interlayer insulating layer and intersects the first horizontal direction, and wherein the first gate electrode extends around the first plurality of nanosheets; a capping layer on an upper surface of the first gate electrode; and an active cut on the upper surface of the lower interlayer insulating layer, wherein the active cut extends in the second horizontal direction and is spaced apart from the first gate electrode in the first horizontal direction, wherein the active cut extends into the active pattern and the second plurality of nanosheets in the vertical direction, wherein an uppermost surface of the active cut is farther than an upper surface of the capping layer from the upper surface of the lower interlayer insulating layer in the vertical direction, and wherein side walls of the active cut are in contact with the second plurality of nanosheets.

According to some embodiments of the present disclosure, there is provided a semiconductor device, comprising a lower interlayer insulating layer; an active pattern on an upper surface of the lower interlayer insulating layer, wherein the active pattern extends in a first horizontal direction that is parallel with the upper surface of the lower interlayer insulating layer, and wherein the active pattern is spaced apart from the upper surface of the lower interlayer insulating layer in a vertical direction that is perpendicular to the upper surface of the lower interlayer insulating layer; a first gate electrode on the active pattern, wherein the first gate electrode extends in a second horizontal direction that is parallel with the upper surface of the lower interlayer insulating layer and intersects the first horizontal direction; a second gate electrode on the active pattern, wherein the second gate electrode extends in the second horizontal direction and is spaced apart from the first gate electrode in the first horizontal direction; an active cut on the upper surface of the lower interlayer insulating layer, wherein the active cut extends in the second horizontal direction between the first gate electrode and the second gate electrode in the first horizontal direction, and wherein the active cut is spaced apart from each of the first gate electrode and the second gate electrode in the first horizontal direction; a first gate spacer on side walls of the first gate electrode; a second gate spacer on side walls of the second gate electrode; a third gate spacer on side walls of the active cut; and a capping layer that is in contact with upper surfaces of the first gate electrode and the second gate electrode and upper surfaces of the first gate spacer, the second gate spacer, and the third gate spacer, wherein the active cut extends into the active pattern and the capping layer in the vertical direction, and wherein an uppermost surface of the active cut is farther than an upper surface of the capping layer from the upper surface of the lower interlayer insulating layer in the vertical direction.

According to some embodiments of the present disclosure, there is provided a semiconductor device, comprising a lower interlayer insulating layer; an active pattern extending on an upper surface of the lower interlayer insulating layer, wherein the active pattern extends in a first horizontal direction that is parallel with the upper surface of the lower interlayer insulating layer, and wherein the active pattern is spaced apart from the upper surface of the lower interlayer insulating layer in a vertical direction that is perpendicular to the upper surface of the lower interlayer insulating layer; a first plurality of nanosheets that are spaced apart from each other in the vertical direction on the active pattern; a second plurality of nanosheets that are spaced apart from each other in the vertical direction on the active pattern, wherein the second plurality of nanosheets are spaced apart from the first plurality of nanosheets in the first horizontal direction; a third plurality of nanosheets that are spaced apart from each other in the vertical direction on the active pattern, wherein the third plurality of nanosheets are between the first plurality of nanosheets and the second plurality of nanosheets in the first horizontal direction; a first gate electrode on the active pattern, wherein the first gate electrode extends in a second horizontal direction that is parallel with the upper surface of the lower interlayer insulating layer and intersects the first horizontal direction, and wherein the first gate electrode extends around the first plurality of nanosheets; a second gate electrode on the active pattern, wherein the second gate electrode extends in the second horizontal direction and is spaced apart from the first gate electrode in the first horizontal direction, and wherein the second gate electrode extends around the second plurality of nanosheets; a lower separation layer on the upper surface of the lower interlayer insulating layer, wherein the lower separation layer extends into the active pattern in the vertical direction, and wherein the lower separation layer overlaps the first gate electrode in the vertical direction; an active cut on the upper surface of the lower interlayer insulating layer, wherein the active cut extends in the second horizontal direction, wherein the active cut is between the first gate electrode and the second gate electrode in the first horizontal direction, wherein the active cut is spaced apart from the lower separation layer in the first horizontal direction, and wherein the active cut extends into the active pattern and the third plurality of nanosheets in the vertical direction; a lower via between the upper surface of the lower interlayer insulating layer and a lower surface of the active pattern, wherein the lower via is in contact with side walls the active cut and side walls of the lower separation layer; a source/drain region on the active pattern, wherein the source/drain region is between the first plurality of nanosheets and the second plurality of nanosheets in the first horizontal direction; a lower source/drain contact on an upper surface of the lower via, wherein the lower source/drain contact extends into the active pattern, and wherein the lower source/drain contact is electrically connected to the source/drain region; a first gate spacer on side walls of the first gate electrode; a second gate spacer on side walls of the second gate electrode; a third gate spacer on the side walls of the active cut; and a capping layer that is in contact with upper surfaces of the first gate electrode and the second gate electrode and upper surfaces of the first gate spacer, the second gate spacer, and the third gate spacer, wherein the active cut extends into the capping layer in the vertical direction, wherein an uppermost surface of the active cut is farther than an upper surface of the capping layer from the upper surface of the lower interlayer insulating layer in the vertical direction, and wherein at least a part of the active pattern is between the lower source/drain contact and the active cut in the first horizontal direction.

However, aspects of the present disclosure are not restricted to the one set forth herein. The above and other aspects of the present disclosure will become more apparent to one of ordinary skill in the art to which the present disclosure pertains by referencing the detailed description of the present disclosure given below.

### BRIEF DESCRIPTION OF THE DRAWINGS

The above and other aspects and features of the present disclosure will become more apparent by describing in detail embodiments thereof referring to the attached drawings, in which:

FIG. 1 is a layout diagram for explaining a semiconductor device according to some embodiments of the present disclosure;

FIG. 2 is a cross-sectional view taken along line A-A′ of FIG. 1;

FIG. 3 is a cross-sectional view taken along line B-B′ of FIG. 1;

FIG. 4 is a cross-sectional view taken along line C-C′ of FIG. 1;

FIGS. 5 to 32 are intermediate process diagrams for explaining a method for fabricating the semiconductor device according to some embodiments of the present disclosure;

FIG. 33 is a cross-sectional view for explaining a semiconductor device according to some embodiments of the present disclosure;

FIG. 34 is a cross-sectional view for explaining a semiconductor device according to some embodiments of the present disclosure;

FIG. 35 is a cross-sectional view for explaining a semiconductor device according to some embodiments of the present disclosure;

FIG. 36 is a cross-sectional view for explaining a semiconductor device according to some embodiments of the present disclosure;

FIGS. 37 to 41 are intermediate process diagrams for explaining a method for fabricating a semiconductor device according to some embodiments of the present disclosure; and

FIG. 42 is a cross-sectional view for explaining a semiconductor device according to some embodiments of the present disclosure.

### DETAILED DESCRIPTION OF THE INVENTION

Although a semiconductor device will be described as including a MBCFET™ (Multi-Bridge Channel Field Effect Transistor) including a nanosheet as an example in drawings of the semiconductor device according to some embodiments, the present disclosure is not limited thereto. In some embodiments, the semiconductor device may include a fin-type transistor (FinFET), a tunneling transistor (tunneling FET), and/or a three-dimensional (3D) transistor including a channel region of a fin-type pattern shape. The semiconductor device according to some embodiments may include a bipolar junction transistor, a laterally diffused metal oxide semiconductor (LDMOS), and/or the like. The term “and/or” includes any and all combinations of one or more of the associated listed items.

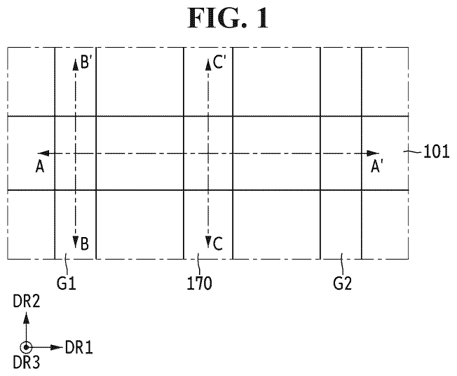

A semiconductor device according to some embodiments of the present disclosure will be described below referring to FIGS. 1 to 4.

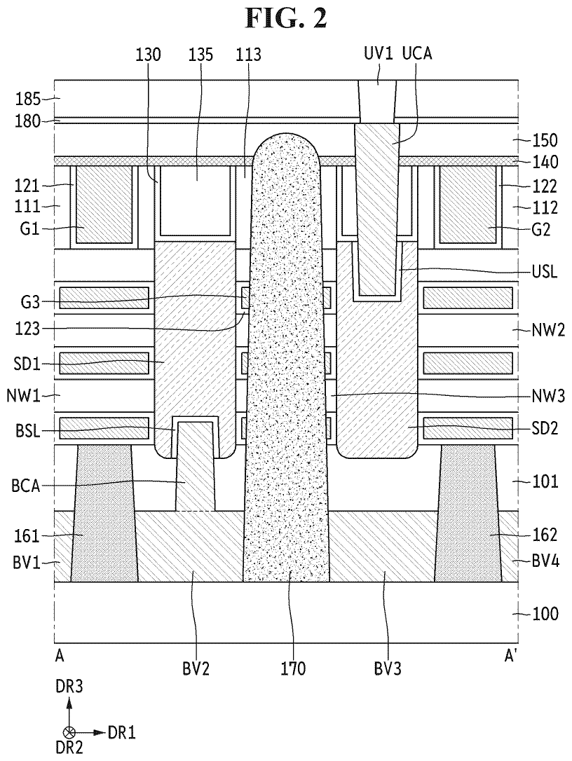

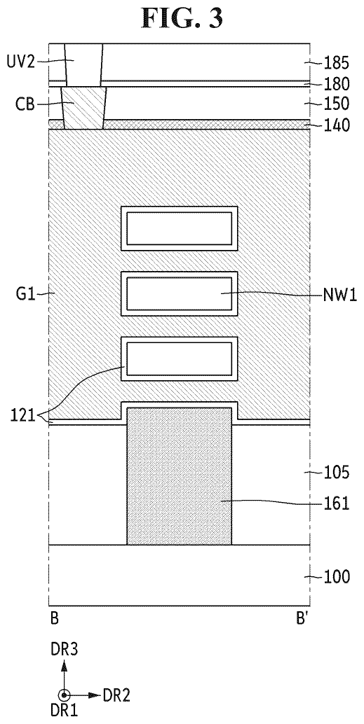

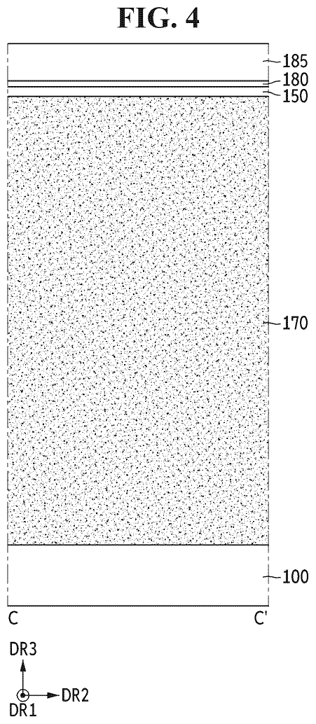

FIG. 1 is a layout diagram for explaining the semiconductor device according to some embodiments of the present disclosure. FIG. 2 is a cross-sectional view taken along line A-A′ of FIG. 1. FIG. 3 is a cross-sectional view taken along line B-B′ of FIG. 1. FIG. 4 is a cross-sectional view taken along line C-C′ of FIG. 1.

Referring to FIGS. 1 to 4, the semiconductor device according to some embodiments of the present disclosure may include a lower interlayer insulating layer 100, an active pattern 101, a field insulating layer 105, first, second, and third plurality of nanosheets NW1, NW2 and NW3, first, second, and third gate electrodes G1, G2 and G3, first, second, and third gate spacers 111, 112 and 113, first, second, and third gate insulating layers 121, 122 and 123, first and second source/drain regions SD1 and SD2, a first etching stop layer 130, a first upper interlayer insulating layer 135, a capping layer 140, a second upper interlayer insulating layer 150, first and second lower separation layers 161 and 162, an active cut 170, a gate contact CB, an upper source/drain contact UCA, a lower source/drain contact BCA, an upper silicide layer USL, a lower silicide layer BSL, first, second, third, and fourth lower vias BV1, BV2, BV3 and BV4, a second etching stop layer 180, a third upper interlayer insulating layer 185, and first and second upper vias UV1 and UV2.

The lower interlayer insulating layer 100 may include, for example, silicon oxide, silicon nitride, silicon oxynitride, and/or a low dielectric constant material. The low dielectric constant material may refer to a material having a dielectric constant less than that of silicon oxide. The low dielectric constant material may include, for example, but not limited to, Fluorinated TetraEthylOrthoSilicate (FTEOS), Hydrogen SilsesQuioxane (HSQ), Bis-benzoCycloButene (BCB), TetraMethylOrthoSilicate (TMOS), OctaMethyleyCloTetraSiloxane (OMCTS), HexaMethylDiSiloxane (HMDS), TriMethylSilyl Borate (TMSB), DiAcetoxyDitertiaryButoSiloxane (DADBS), TriMethylSilil Phosphate (TMSP), PolyTetraFluoroEthylene (PTFE), TOSZ (Tonen SilaZen), FSG (Fluoride Silicate Glass), polyimide nanofoams such as polypropylene oxide, CDO (Carbon Doped silicon Oxide), OSG (Organo Silicate Glass), SILK, Amorphous Fluorinated Carbon, silica aerogels, silica xerogels, mesoporous silica, and/or combinations thereof. However, the present disclosure is not limited thereto.

Hereinafter, each of a first direction DR1 (a first horizontal direction DR1) and a second direction DR2 (a second horizontal direction DR2) may be defined as a direction parallel to an upper surface of the lower interlayer insulating layer 100. The second horizontal direction DR2 may be defined as a direction different from the first horizontal direction DR1. The third direction DR3 (the vertical direction DR3) may be defined as a direction perpendicular to each of the first horizontal direction DR1 and the second horizontal direction DR2. That is, the vertical direction DR3 may be defined as a direction perpendicular to the upper surface of the lower interlayer insulating layer 100.

The active pattern 101 may extend in the first horizontal direction DR1 on the upper surface of the lower interlayer insulating layer 100. For example, the active pattern 101 may be spaced from the upper surface of the lower interlayer insulating layer 100 in the vertical direction DR3. For example, the active pattern 101 may include silicon (Si). The field insulating layer 105 may be disposed on the upper surface of the lower interlayer insulating layer 100. The field insulating layer 105 may extend around (e.g., surround) a side wall of the active pattern 101. For example, the upper surface of the active pattern 101 may protrude beyond (above) the upper surface of the field insulating layer 105 in the vertical direction DR3. However, the present disclosure is not limited thereto. In some embodiments, the upper surface of the active pattern 101 may be formed on the same plane as the upper surface of the field insulating layer 105. For example, the upper surface of the active pattern 101 and the upper surface of the field insulating layer 105 may be coplanar with each other. For example, the field insulating layer 105 may include an oxide film, a nitride film, an oxynitride film, and/or a combination thereof.

Each of the first, second, and third plurality of nanosheets NW1, NW2 and NW3 may be disposed on the active pattern 101. The second plurality of nanosheets NW2 may be spaced apart from the first plurality of nanosheets NW1 in the first horizontal direction DR1. The third plurality of nanosheets NW3 may be disposed between the first plurality of nanosheets NW1 and the second plurality of nanosheets NW2 (in the first horizontal direction DR1). The third plurality of nanosheets NW3 may be spaced apart from the first plurality of nanosheets NW1 in the first horizontal direction DR1. The second plurality of nanosheets NW2 may be spaced apart from the third plurality of nanosheets NW3 in the first horizontal direction DR1.

Each of the first, second, and third plurality of nanosheets NW1, NW2 and NW3 may include a plurality of nanosheets stacked to be spaced apart from each other in the vertical direction DR3. In FIGS. 2 and 3, each of the first, second, and third plurality of nanosheets NW1, NW2 and NW3 is shown as including three nanosheets stacked to be spaced apart from each other in the vertical direction DR3, but the present disclosure is not limited thereto. In some embodiments, each of the first, second, and third plurality of nanosheets NW1, NW2 and NW3 may include four or more nanosheets stacked to be spaced apart from each other in the vertical direction DR3. For example, each of the first, second, and third plurality of nanosheets NW1, NW2 and NW3 may include silicon (Si). However, the present disclosure is not limited thereto. In some embodiments, each of the first, second, and third plurality of nanosheets NW1, NW2 and NW3 may include silicon germanium (SiGe).

Each of the first, second, and third gate electrodes G1, G2 and G3 may extend in the second horizontal direction DR2 on the active pattern 101 and the field insulating layer 105. The third gate electrode G3 may be disposed between the first gate electrode G1 and the second gate electrode G2 (in the first horizontal direction DR1). The third gate electrode G3 may be spaced apart from the first gate electrode G1 in the first horizontal direction DR1. The second gate electrode G2 may be spaced apart from the third gate electrode G3 in the first horizontal direction DR1. For example, the first gate electrode G1 may extend around (e.g., surround) the first plurality of nanosheets NW1. The second gate electrode G2 may extend around (e.g., surround) the second plurality of nanosheets NW2. The third gate electrode G3 may extend around (e.g., surround) the third plurality of nanosheets NW3.

For example, each of the first, second, and third gate electrodes G1, G2 and G3 may include titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAIC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and/or combinations thereof. Each of the first, second, and third gate electrodes G1, G2 and G3 may include a conductive metal oxide, a conductive metal oxynitride, and/or the like, and/or may include oxidized forms of the aforementioned materials.

A first gate spacer 111 may extend in the second horizontal direction DR2 along both side walls (e.g., opposite side walls) of the first gate electrode G1 in the first horizontal direction DR1, on the upper surface of the uppermost nanosheet of the first plurality of nanosheets NW1 and the field insulating layer 105. The second gate spacer 112 may extend in the second horizontal direction DR2 along both side walls (e.g., opposite side walls) of the second gate electrode G2 in the first horizontal direction DR1, on the upper surface of the uppermost nanosheet of the second plurality of nanosheets NW2 and the field insulating layer 105. The third gate spacer 113 may extend in the second horizontal direction DR2 along both side walls (e.g., opposite side walls) of the active cut 170 in the first horizontal direction DR1, on the upper surface of the uppermost nanosheet of the third plurality of nanosheets NW3 and the field insulating layer 105. A detailed description of the active cut 170 will be provided below.

For example, the upper surfaces of each of the first, second, and third gate spacers 111, 112 and 113 may be formed on the same plane as the upper surfaces of each of the first and second gate electrodes G1 and G2. The upper surfaces of each of the first, second, and third gate spacers 111, 112, and 113 may be coplanar with the upper surface of each of the first and second gate electrodes G1 and G2. For example, each of the first, second, and third gate spacers 111, 112 and 113 may include, for example, but not limited to, silicon nitride (SiN), silicon oxynitride (SiON), silicon carbonitride (SiCN), silicon oxide (SiO₂), silicon oxycarbonitride (SiOCN), silicon boronitride (SiBN), silicon oxyboronitride (SiOBN), silicon oxycarbide (SiOC), and/or combinations thereof. However, the present disclosure is not limited thereto.

A first source/drain region SD1 may be disposed on the active pattern 101 between the first plurality of nanosheets NW1 and first outer walls of the third plurality of nanosheets NW3. For example, the first source/drain region SD1 may be in contact with each of the side walls of the first plurality of nanosheets NW1 in the first horizontal direction DR1 and the first outer walls (e.g., each of the side walls) of the third plurality of nanosheets NW3 in the first horizontal direction DR1. The second source/drain region SD2 may be disposed on the active pattern 101 between second outer walls (e.g., each of the side walls) of the third plurality of nanosheets NW3 and the second plurality of nanosheets NW2 in the first horizontal direction DR1. The second outer walls of the third plurality of nanosheets NW3 may be defined as outer walls that are opposite to the first outer walls of the third plurality of nanosheets NW3 in the first horizontal direction DR1. For example, the second source/drain region SD2 may be in contact with each of the second outer walls of the third plurality of nanosheets NW3 and the side walls of the second plurality of nanosheets NW2 in the first horizontal direction DR1.

A first gate insulating layer 121 may be disposed between the first gate electrode G1 and the active pattern 101. The first gate insulating layer 121 may be disposed between the first gate electrode G1 and a first lower separation layer 161. The first gate insulating layer 121 may be disposed between the first gate electrode G1 and the field insulating layer 105. The first gate insulating layer 121 may be disposed between the first gate electrode G1 and the first gate spacer 111. The first gate insulating layer 121 may be disposed between the first gate electrode G1 and the first plurality of nanosheets NW1. The first gate insulating layer 121 may be disposed between the first gate electrode G1 and the first source/drain region SD1. For example, the first gate insulating layer 121 may be in contact with the first source/drain region SD1.

A second gate insulating layer 122 may be disposed between the second gate electrode G2 and the active pattern 101. The second gate insulating layer 122 may be disposed between the second gate electrode G2 and a second lower separation layer 162. The second gate insulating layer 122 may be disposed between the second gate electrode G2 and the field insulating layer 105. The second gate insulating layer 122 may be disposed between the second gate electrode G2 and the second gate spacer 112. The second gate insulating layer 122 may be disposed between the second gate electrode G2 and the second plurality of nanosheets NW2. The second gate insulating layer 122 may be disposed between the second gate electrode G2 and the second source/drain region SD2. For example, the second gate insulating layer 122 may be in contact with the second source/drain region SD2.

A third gate insulating layer 123 may be disposed between the third gate electrode G3 and the active pattern 101. The third gate insulating layer 123 may be disposed between the third gate electrode G3 and the field insulating layer 105. The third gate insulating layer 123 may be disposed between the third gate electrode G3 and the third plurality of nanosheets NW3. The third gate insulating layer 123 may be disposed between the third gate electrode G3 and the first source/drain region SD1. The third gate insulating layer 123 may be disposed between the third gate electrode G3 and the second source/drain region SD2. For example, the third gate insulating layer 123 may be in contact with each of the first and second source/drain regions SD1 and SD2. For example, the uppermost surfaces of each of the first and second gate insulating layers 121 and 122 may be formed on the same plane as (e.g., may be coplanar with) the upper surfaces of each of the first and second gate electrodes G1 and G2 and the upper surfaces of each of the first, second, and third gate spacers 111, 112 and 113

Each of the first, second, and third gate insulating layers 121, 122 and 123 may include, for example, silicon oxide, silicon oxynitride, silicon nitride, and/or a high dielectric constant material having a dielectric constant greater than that of silicon oxide. The high dielectric constant material may include, for example, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate.

A semiconductor device according to some embodiments may include a NC (Negative Capacitance) FET that uses a negative capacitor. For example, (each of) the first, second, and third gate insulating layers 121, 122 and 123 may include a ferroelectric material film having ferroelectric properties and/or a paraelectric material film having paraelectric properties.

The ferroelectric material film may have a negative capacitance, and the paraelectric material film may have a positive capacitance. For example, if two or more capacitors are (electrically) connected in series and the capacitance of each capacitor has a positive value, the overall capacitances decrease from the capacitance of each of the individual capacitors. On the other hand, if at least one of the capacitances of two or more capacitors (electrically) connected in series has a negative value, the overall capacitances may be greater than an absolute value of each of the individual capacitances, while having a positive value.

When the ferroelectric material film having the negative capacitance and the paraelectric material film having the positive capacitance are (electrically) connected in series, the overall capacitance values of the ferroelectric material film and the paraelectric material film (electrically) connected in series may increase. By the use of the increased overall capacitance value, a transistor including the ferroelectric material film may have a subthreshold swing (SS), for example, under 60 mV/decade at room temperature.

The ferroelectric material film may have ferroelectric properties. The ferroelectric material film may include, for example, hafnium oxide, hafnium zirconium oxide, barium strontium titanium oxide, barium titanium oxide, and/or lead zirconium titanium oxide. Here, as an example, the hafnium zirconium oxide may be a material obtained by doping hafnium oxide with zirconium (Zr). As an example, the hafnium zirconium oxide may be a compound of hafnium (Hf), zirconium (Zr), and oxygen (O).

The ferroelectric material film may further include a doped dopant. For example, the dopant may include aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and/or tin (Sn). The type of dopant included in the ferroelectric material film may vary, depending on which type of ferroelectric material is included in the ferroelectric material film.

When the ferroelectric material film includes hafnium oxide, the dopant included in the ferroelectric material film may include, for example, gadolinium (Gd), silicon (Si), zirconium (Zr), aluminum (Al), and/or yttrium (Y).

When the dopant is aluminum (Al), the ferroelectric material film may include, for example, 3 to 8 at % (atomic %) aluminum. Here, a ratio of the dopant may be a ratio of dopant (e.g., aluminum) to the sum of hafnium and the dopant (e.g., aluminum).

When the dopant is silicon (Si), the ferroelectric material film may include, for example, 2 to 10 at % silicon. When the dopant is yttrium (Y), the ferroelectric material film may include, for example, 2 to 10 at % yttrium. When the dopant is gadolinium (Gd), the ferroelectric material film may include, for example, 1 to 7 at % gadolinium. When the dopant is zirconium (Zr), the ferroelectric material film may include, for example, 50 to 80 at % zirconium.

The paraelectric material film may have the paraelectric properties. The paraelectric material film may include, a silicon oxide and/or a metal oxide having a high dielectric constant. The metal oxide included in the paraelectric material film may include, for example, but not limited to, hafnium oxide, zirconium oxide, and/or aluminum oxide.

In some embodiments, the ferroelectric material film and the paraelectric material film may include the same material. The ferroelectric material film may have the ferroelectric properties, but the paraelectric material film may not have the ferroelectric properties. For example, when the ferroelectric material film and the paraelectric material film include hafnium oxide, a crystal structure of hafnium oxide included in the ferroelectric material film differs from a crystal structure of hafnium oxide included in the paraelectric material film.

The ferroelectric material film may have a thickness having the ferroelectric properties. The thickness of the ferroelectric material film may be, for example, but not limited to, 0.5 to 10 nanometers (nm). Since a critical thickness that exhibits the ferroelectric properties may vary for each ferroelectric material, the thickness of the ferroelectric material film may vary depending on the ferroelectric material.

As an example, each of the first, second, and third gate insulating layers 121, 122 and 123 may include a ferroelectric material film. As an example, each of the first, second, and third gate insulating layers 121, 122 and 123 may include a plurality of ferroelectric material films spaced apart from each other. Each of the first, second, and third gate insulating layers 121, 122 and 123 may have a stacked film structure in which the plurality of ferroelectric material films and the plurality of paraelectric material films are (alternately) stacked.

The first etching stop layer 130 may be disposed on the side walls of each of the first, second, and third gate spacers 111, 112 and 113 in the first horizontal direction DR1. The first etching stop layer 130 may be disposed on the upper surface of each of the first and second source/drain regions SD1 and SD2. Although not shown, the first etching stop layer 130 may be disposed on the side walls of each of the first and second source/drain regions SD1 and SD2 in the second horizontal direction DR2. For example, the first etching stop layer 130 may be formed conformally. The first etching stop layer 130 may include, for example, aluminum oxide, aluminum nitride, hafnium oxide, zirconium oxide, silicon oxide, silicon nitride, silicon oxynitride, and/or a low dielectric constant material.

The first upper interlayer insulating layer 135 may be disposed on the first etching stop layer 130. The first upper interlayer insulating layer 135 may be on (e.g., may cover) each of the first and second source/drain regions SD1 and SD2. For example, the upper surface of the first upper interlayer insulating layer 135 may be formed on the same plane as (may be coplanar with) each of the upper surfaces of the first and second gate electrodes G1 and G2 and each of the upper surfaces of the first, second, and third gate spacers 111, 112 and 113. For example, the first upper interlayer insulating layer 135 may include, for example, silicon oxide, silicon nitride, silicon oxynitride, and/or a low dielectric constant material.

The capping layer 140 may be disposed on each of the upper surfaces of the first and second gate electrodes G1 and G2, upper surfaces of the first, second, and third gate spacers 111, 112 and 113, the uppermost surfaces of the first and second gate insulating layers 121 and 122, the uppermost surface of the first etching stop layer 130, and the upper surface of the first upper interlayer insulating layer 135. For example, the capping layer 140 may be in contact with each of the upper surfaces of the first and second gate electrodes G1 and G2, the upper surfaces of the first, second, and third gate spacers 111, 112 and 113, the uppermost surfaces of the first and second gate insulating layers 121 and 122, the uppermost surface of the first etching stop layer 130, and the upper surface of the first upper interlayer insulating layer 135. For example, the capping layer 140 may be formed conformally. For example, the capping layer 140 may be formed integrally. For example, the capping layer 140 that is in contact with each of the first, second, and third gate spacers 111, 112 and 113 may be formed integrally. When a structure is “formed integrally”, it may mean that the structure (e.g., a continuum) is formed without a (visible) boundary between the sub-substructures therein by a same process or a same series of processes.

The capping layer 140 may include an insulating material. For example, the capping layer 140 may include silicon nitride (SiN), silicon oxynitride (SiON), silicon oxide (SiO₂), silicon carbonitride (SiCN), silicon oxycarbonitride (SiOCN), and/or combinations thereof. However, the present disclosure is not limited thereto. The second upper interlayer insulating layer 150 may be disposed on the upper surface of the capping layer 140. For example, the second upper interlayer insulating layer 150 may include silicon oxide, silicon nitride, silicon oxynitride, and/or a low dielectric constant material.

The first lower separation layer 161 may extend in (e.g., penetrate) the active pattern 101 in the vertical direction DR3 on (above) the upper surface of the lower interlayer insulating layer 100. The first lower separation layer 161 may be disposed below the first gate electrode G1. That is, the first lower separation layer 161 may overlap the first gate electrode G1 in the vertical direction DR3. The second lower separation layer 162 may extend in (e.g., penetrate) the active pattern 101 in the vertical direction DR3 on (above) the upper surface of the lower interlayer insulating layer 100. The second lower separation layer 162 may be spaced apart from the first lower separation layer 161 in the first horizontal direction DR1. The second lower separation layer 162 may be disposed below the second gate electrode G2. That is, the second lower separation layer 162 may overlap the second gate electrode G2 in the vertical direction DR3.

For example, each of the first and second lower separation layers 161 and 162 may separate the active pattern 101 in the first horizontal direction DR1. For example, the lower surfaces of each of the first and second lower separation layers 161 and 162 may be in contact with the upper surface of the lower interlayer insulating layer 100. For example, the upper surface of the first lower separation layer 161 may be in contact with the (lowermost) first gate insulating layer 121. For example, the upper surface of the second lower separation layer 162 may be in contact with the (lowermost) second gate insulating layer 122. For example, both side walls (e.g., opposite side walls) of each of the first and second lower separation layers 161 and 162 in the first horizontal direction DR1 may be in contact with the active pattern 101. For example, both side walls (e.g., opposite side walls) of each of the first and second lower separation layers 161 and 162 in the second horizontal direction DR2 may be in contact with the field insulating layer 105. For example, the upper surface of each of the first and second lower separation layers 161 and 162 may be formed to be higher than the upper surface of the field insulating layer 105. Herein, the term “level”, “vertical level”, “height”, or the like may refer to a relative location with respect to a reference element in the third direction DR3 (the vertical direction DR3). A level, a vertical level, height, or the like may be a distance from a lower surface of the lower interlayer insulating layer 100 in the vertical direction DR3. For example, a higher level may mean a farther distance from the lower surface of the lower interlayer insulating layer 100 in the vertical direction DR3, and a lower level may mean a closer distance to the lower surface of the lower interlayer insulating layer 100 in the vertical direction DR3.

For example, widths of the lower surfaces of each of the first and second lower separation layers 161 and 162 in the first horizontal direction DR1 may be greater than widths of the upper surfaces of each of the first and second lower separation layers 161 and 162 in the first horizontal direction DR1, respectively. Each of the first and second lower separation layers 161 and 162 may include an insulating material. For example, each of the first and second lower separation layers 161 and 162 may include silicon nitride (SiN), silicon oxynitride (SiON), silicon carbonitride (SiCN), silicon oxide (SiO₂), silicon oxycarbonitride (SiOCN), silicon boronitride (SiBN), silicon oxyboronitride (SiOBN), silicon oxycarbide (SiOC), and/or combinations thereof. However, the present disclosure is not limited thereto.

The active cut 170 may be disposed on the upper surface of the lower interlayer insulating layer 100. For example, the active cut 170 may extend in the second horizontal direction DR2 between the first gate electrode G1 and the second gate electrode G2 (in the first horizontal direction DR1). The active cut 170 may be spaced apart from each of the first and second gate electrodes G1 and G2 in the first horizontal direction DR1. For example, the active cut 170 may be disposed between the first source/drain region SD1 and the second source/drain region SD2 (in the first horizontal direction DR1). For example, the active cut 170 may be spaced apart from each of the first and second source/drain regions SD1 and SD2 in the first horizontal direction DR1. For example, the active cut 170 may be disposed between the first lower separation layer 161 and the second lower separation layer 162 (in the first horizontal direction DR1). For example, the active cut 170 may be spaced apart from each of the first and second lower separation layers 161 and 162 in the first horizontal direction DR1.

For example, the active cut 170 may extend in (e.g., penetrate) the active pattern 101, the third plurality of nanosheets NW3, the third gate electrode G3, the third gate insulating layer 123, and the capping layer 140 in the vertical direction DR3. For example, both side walls (e.g., opposite side walls) of the active cut 170 in the first horizontal direction DR1 may be in contact with each of the active pattern 101, the third plurality of nanosheets NW3, the third gate electrode G3, the third gate insulating layer 123, and the capping layer 140. For example, both side walls (e.g., opposite side walls) of the active cut 170 in the first horizontal direction DR1 may be in contact with the third gate spacer 113.

For example, at least a part of the active cut 170 may extend into the second upper interlayer insulating layer 150. For example, the upper surface of the active cut 170 may be in contact with the second upper interlayer insulating layer 150. For example, at least a part of the active cut 170 may protrude beyond the upper surface of the capping layer 140 in the vertical direction DR3. That is, the uppermost surface of the active cut 170 may be formed to be higher than the upper surface of the capping layer 140. For example, the lower surface of the active cut 170 may be in contact with the upper surface of the lower interlayer insulating layer 100. For example, the lower surface of the active cut 170 may be formed to be lower than the lower surface of the active pattern 101. For example, the lower surface of the active cut 170 may be formed on the same plane as (may be coplanar with) the lower surfaces of each of the first and second lower separation layers 161 and 162.

For example, the side wall of the active cut 170 in the first horizontal direction DR1 may have a continuous slope profile. However, the present disclosure is not limited thereto. For example, the width of the lower surface of the active cut 170 in the first horizontal direction DR1 may be greater (larger) than the width of the upper surface of the active cut 170 in the first horizontal direction DR1. For example, the active cut 170 may include silicon nitride (SiN), silicon oxynitride (SiON), silicon carbonitride (SiCN), silicon oxycarbonitride (SiOCN), silicon oxycarbide (SiOC), and/or combinations thereof. However, the present disclosure is not limited thereto.

Each of first, second, third, and fourth lower vias BV1 to BV4 may be disposed between the upper surface of the lower interlayer insulating layer 100 and the lower surface of the active pattern 101. For example, the upper surfaces of each of the first, second, third, and fourth lower vias BV1 to BV4 may be in contact with the lower surface of the active pattern 101. The lower surfaces of each of the first, second, third, and fourth lower vias BV1 to BV4 may be in contact with the upper surface of the lower interlayer insulating layer 100. For example, the lower surfaces of each of the first, second, third, and fourth lower vias BV1 to BV4 may be formed on the same plane as (may be coplanar with) the lower surfaces of each of the first and second lower separation layers 161 and 162, the active cut 170, and the field insulating layer 105. For example, both side walls (e.g., opposite side walls) of each of the first, second, third, and fourth lower vias BV1 to BV4 in the second horizontal direction DR2 may be in contact with the field insulating layer 105.

For example, the first lower via BV1 and the second lower via BV2 may be separated in the first horizontal direction DR1 by the first lower separation layer 161. The second lower via BV2 and the third lower via BV3 may be separated in the first horizontal direction DR1 by the active cut 170. The third lower via BV3 and the fourth lower via BV4 may be separated in the first horizontal direction DR1 by the second lower separation layer 162. For example, the second lower via BV2 may be disposed between the first lower separation layer 161 and the active cut 170. Both side walls (e.g., opposite side walls) of the second lower via BV2 in the first horizontal direction DR1 may be in contact with the first lower separation layer 161 and the active cut 170. For example, the third lower via BV3 may be disposed between the active cut 170 and the second lower separation layer 162. Both side walls (e.g., opposite side walls) of the third lower via BV3 in the first horizontal direction DR1 may be in contact with the active cut 170 and the second lower separation layer 162. For example, each of the first, second, third, and fourth lower vias BV1 to BV4 may include a conductive material.

The lower source/drain contact BCA may extend in (e.g., penetrate) the active pattern 101 in the vertical direction DR3 on the upper surface of the second lower via BV2. For example, at least a part of the lower source/drain contact BCA may extend into the first source/drain region SD1. The lower source/drain contact BCA may be (electrically) connected to the first source/drain region SD1. For example, the lower surface of the lower source/drain contact BCA may be in contact with the upper surface of the second lower via BV2. For example, the lower source/drain contact BCA may be integrally formed with the second lower via BV2.

For example, the lower source/drain contact BCA may be disposed between the first lower separation layer 161 and the active cut 170 (in the first horizontal direction DR1). For example, the lower source/drain contact BCA may be separated from each of the first lower separation layer 161 and the active cut 170 in the first horizontal direction DR1. For example, at least a part of the active pattern 101 may be disposed between the first lower separation layer 161 and the lower source/drain contact BCA (in the first horizontal direction DR1). In some embodiments, at least a part of the active pattern 101 may be disposed between the lower source/drain contact BCA and the active cut 170 (in the first horizontal direction DR1). The lower source/drain contact BCA may include a conductive material.

The upper source/drain contact UCA may be disposed between the active cut 170 and the second gate electrode G2 (in the first horizontal direction DR1). The upper source/drain contact UCA may extend in (e.g., penetrate) the second upper interlayer insulating layer 150, the capping layer 140, the first upper interlayer insulating layer 135, and the first etching stop layer 130 in the vertical direction DR3, and may extend into the second source/drain region SD2. The upper source/drain contact UCA may be (electrically) connected to the second source/drain region SD2. For example, the upper surface of the upper source/drain contact UCA may be formed on the same plane as (may be coplanar with) the upper surface of the second upper interlayer insulating layer 150. For example, the upper surface of the upper source/drain contact UCA may be formed to be higher than the uppermost surface of the active cut 170. However, the present disclosure is not limited thereto. The upper source/drain contact UCA may include a conductive material.

The lower silicide layer BSL may be disposed along an interface between the lower source/drain contact BCA and the first source/drain region SD1. The upper silicide layer USL may be disposed along the interface between the upper source/drain contact UCA and the second source/drain region SD2. The lower silicide layer BSL may be between the lower source/drain contact BCA and the first source/drain region SD1. The upper silicide layer USL may be between the upper source/drain contact UCA and the second source/drain region SD2. The lower source/drain contact BCA and the first source/drain region SD1 may be spaced apart from each other by the lower silicide layer BSL. The upper source/drain contact UCA and the second source/drain region SD2 may be spaced apart from each other by the upper silicide layer USL. For example, each of the lower silicide layer BSL and the upper silicide layer USL may include a metal silicide material. The gate contact CB may extend in (e.g., penetrate) the second upper interlayer insulating layer 150 and the capping layer 140 in the vertical direction DR3, and may be (electrically) connected to the first gate electrode G1. For example, the upper surface of the gate contact CB may be formed on the same plane as (may be coplanar with) the upper surface of the second upper interlayer insulating layer 150, but the present disclosure is not limited thereto. The gate contact CB may include a conductive material.

The second etching stop layer 180 may be disposed on the upper surface of the second upper interlayer insulating layer 150. For example, the second etching stop layer 180 may be spaced apart from the uppermost surface of the active cut 170 in the vertical direction DR3. However, the present disclosure is not limited thereto. In some embodiments, the second etching stop layer 180 may be in contact with the uppermost surface of the active cut 170. For example, the second etching stop layer 180 may include aluminum oxide, aluminum nitride, hafnium oxide, zirconium oxide, silicon oxide, silicon nitride, silicon oxynitride, and/or a low dielectric constant material. The third upper interlayer insulating layer 185 may be disposed on the upper surface of the second etching stop layer 180. For example, the third upper interlayer insulating layer 185 may include silicon oxide, silicon nitride, silicon oxynitride, and/or a low dielectric constant material.

A first upper via UV1 may extend in (e.g., penetrate) the third upper interlayer insulating layer 185 and the second etching stop layer 180 in the vertical direction DR3, and may be (electrically) connected to the upper source/drain contact UCA. The second upper via UV2 may extend in (e.g., penetrate) the third upper interlayer insulating layer 185 and the second etching stop layer 180 in the vertical direction DR3, and may be (electrically) connected to the gate contact CB. Each of the first and second upper vias UV1 and UV2 may include a conductive material.

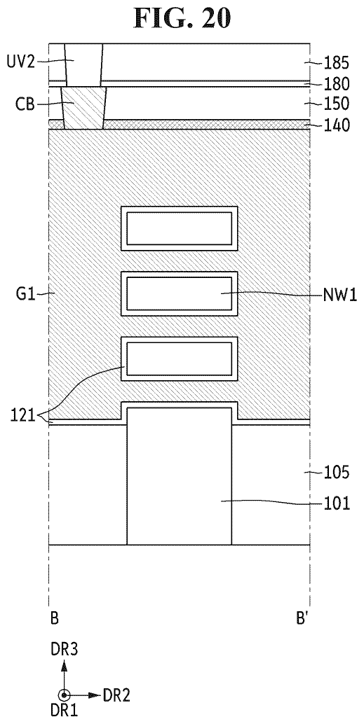

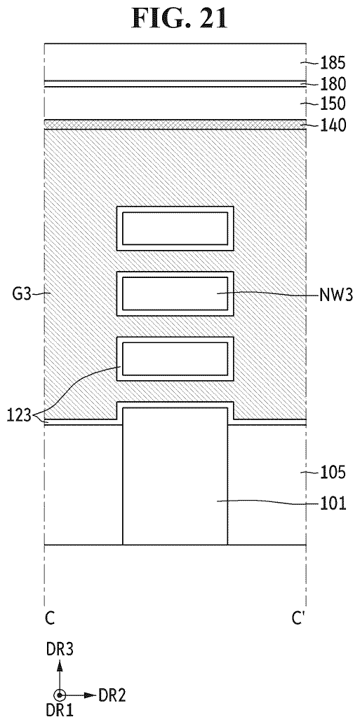

Hereinafter, a method for fabricating a semiconductor device according to some embodiments of the present disclosure will be described referring to FIGS. 2 to 32.

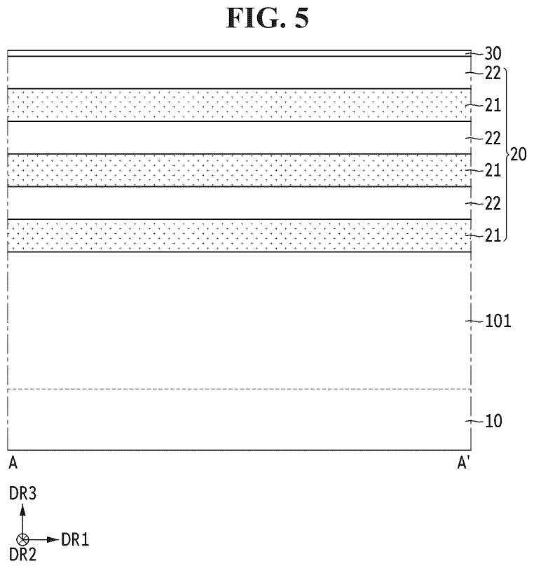

FIGS. 5 to 32 are intermediate step diagrams for describing the method for fabricating the semiconductor device according to some embodiments of the present disclosure.

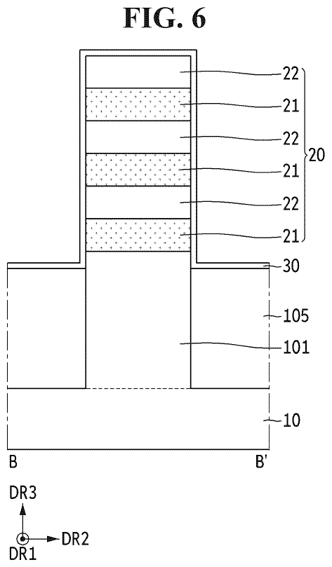

Referring to FIGS. 5 and 6, a substrate 10 may be provided. The substrate 10 may be a silicon substrate or a silicon-on-insulator (SOI). In some embodiments, the substrate 10 may include silicon germanium, silicon germanium on insulator (SGOI), indium antimonide, lead telluride, indium arsenide, indium phosphide, gallium arsenide, and/or gallium antimonide, but the present disclosure is not limited thereto.

Next, a stacked structure 20 may be formed on the upper surface of the substrate 10. The stacked structure 20 may include a first semiconductor layer 21 and a second semiconductor layer 22 that are alternately stacked on the upper surface of the substrate 10. For example, the first semiconductor layer 21 may be formed on the lowermost part of the stacked structure 20, and the second semiconductor layer 22 may be formed on the uppermost part of the stacked structure 20. However, the present disclosure is not limited thereto. In some embodiments, the first semiconductor layer 21 may be formed on the uppermost part of the stacked structure 20. The first semiconductor layer 21 may include, for example, silicon germanium (SiGe). The second semiconductor layer 22 may include, for example, silicon (Si).

Next, a part of the stacked structure 20 may be etched. A part of the substrate 10 may be etched, while the stacked structure 20 is being etched. An active pattern 101 may be defined below the stacked structure 20 on the upper surface of the substrate 10 through such an etching process. The active pattern 101 may protrude from an upper surface (e.g., a recessed upper surface by the etching process) of the substrate 10 in the vertical direction DR3. The active pattern 101 may extend in the first horizontal direction DR1.

Next, the field insulating layer 105 may be formed on the upper surface of the substrate 10. The field insulating layer 105 may extend around (e.g., surround) the side walls of the active pattern 101. For example, the upper surface of the active pattern 101 may be formed to be higher than the upper surface of the field insulating layer 105. Next, a pad oxide layer 30 may be formed to be on (e.g., to cover) the upper surface of the field insulating layer 105, the side walls of the exposed active pattern 101, and the side walls and upper surface of the stacked structure 20. For example, the pad oxide layer 30 may be formed conformally. The pad oxide layer 30 may include, for example, silicon oxide (SiO₂).

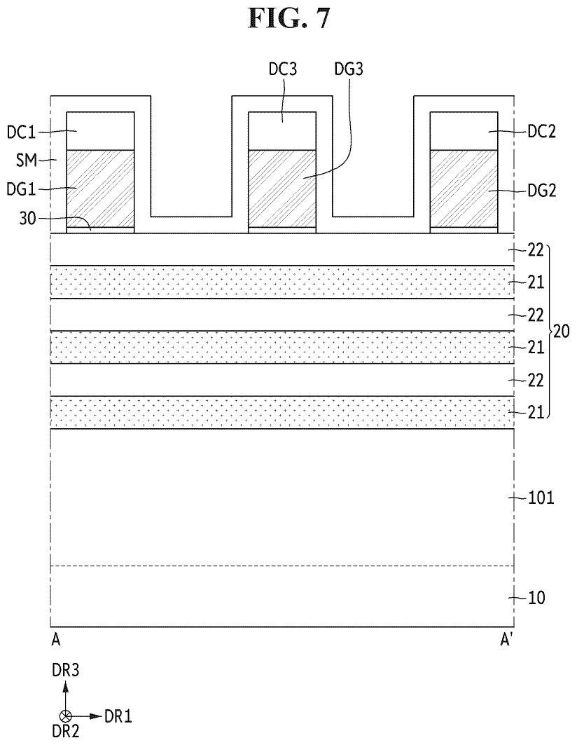

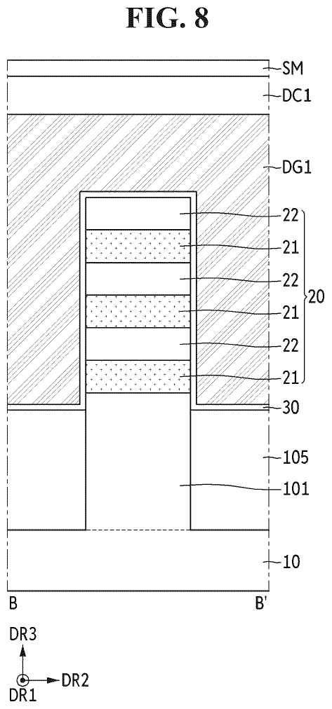

Referring to FIGS. 7 and 8, first, second, and third dummy gates DG1, DG2 and DG3 and first, second, and third dummy capping patterns DC1, DC2 and DC3 that extend in the second horizontal direction DR2 on the pad oxide layer 30 may be formed over (on) the stacked structure 20 and the field insulating layer 105. Specifically, the third dummy gate DG3 may be spaced apart from the first dummy gate DG1 in the first horizontal direction DR1. The second dummy gate DG2 may be spaced apart from the third dummy gate DG3 in the first horizontal direction DR1. The first dummy capping pattern DC1 may be disposed on the first dummy gate DG1. The second dummy capping pattern DC2 may be disposed on the second dummy gate DG2. The third dummy capping pattern DC3 may be disposed on the third dummy gate DG3. While the first, second, and third dummy gates DG1, DG2 and DG3 and the first, second, and third dummy capping patterns DC1, DC2 and DC3 are being formed, the remaining pad oxide layer 30 except for the portions that overlap the first, second, and third dummy gates DG1, DG2 and DG3 in the vertical direction DR3 on the substrate 10 may be removed.

Next, a spacer material layer SM may be on (e.g., may be formed to cover) the side walls of each of the first, second, and third dummy gates DG1, DG2 and DG3, the side walls and upper surfaces of each of the first, second, and third dummy capping patterns DC1, DC2 and DC3, the side wall and upper surface of the exposed stacked structure 20, and the upper surface of the field insulating layer 105. For example, the spacer material layer SM may be formed conformally. The spacer material layer SM may include, for example, silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and/or combinations thereof.

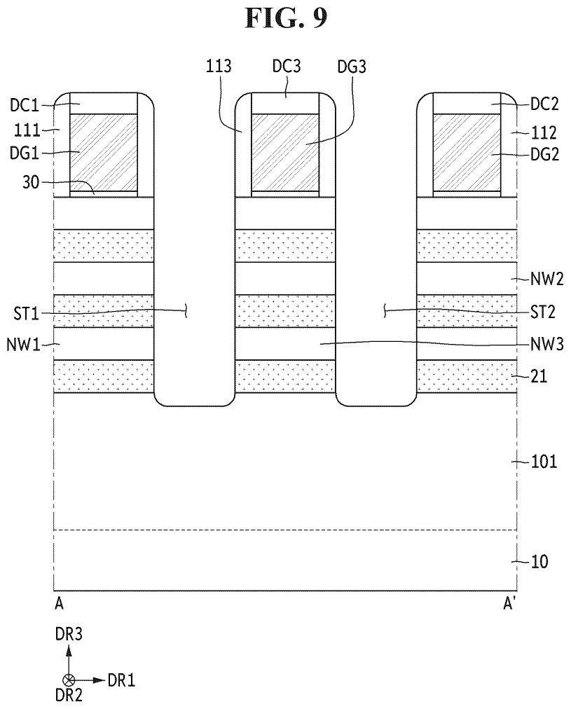

Referring to FIG. 9, the stacked structure (the stacked structure 20 of FIG. 7) may be etched using the first, second, and third dummy gates DG1, DG2 and DG3 and the first, second, and third dummy capping patterns DC1, DC2 and DC3 as a mask, thereby forming the first and second source/drain trenches ST1 and ST2. A first source/drain trench ST1 may be formed between the first dummy gate DG1 and the third dummy gate DG3 (in the first horizontal direction DR1). A second source/drain trench ST2 may be formed between the third dummy gate DG3 and the second dummy gate DG2 (in the first horizontal direction DR1). For example, each of the first and second source/drain trenches ST1 and ST2 may extend in (may extend into) the active pattern 101.

For example, while each of the first and second source/drain trenches ST1 and ST2 is being formed, the spacer material layer (the spacer material layer SM of FIG. 7) formed on the upper surface of each of the first, second, and third dummy capping patterns DC1, DC2, and DC3, and a part of each of the first, second, and third dummy capping patterns DC1, DC2, and DC3 may be etched. The spacer material layer (the spacer material layer SM of FIG. 7) that remains on the side walls of each of the first, second, and third dummy capping patterns DC1, DC2, and DC3 and the first, second, and third dummy gates DG1, DG2, and DG3 may be defined as first, second, and third gate spacers 111, 112 and 113.

For example, after each of the first and second source/drain trenches ST1 and ST2 is formed, the second semiconductor layers (the second semiconductor layers 22 of FIG. 7) that remain below the first dummy gate DG1 on the active pattern 101 may be defined as a first plurality of nanosheets NW1. After each of the first and second source/drain trenches ST1 and ST2 is formed, the second semiconductor layers (the second semiconductor layers 22 of FIG. 7) that remain below the second dummy gate DG2 on the active pattern 101 may be defined as a second plurality of nanosheets NW2. After each of the first and second source/drain trenches ST1 and ST2 is formed, the second semiconductor layer (the second semiconductor layers 22 of FIG. 7) that remain below the third dummy gate DG3 on the active pattern 101 may be defined as a third plurality of nanosheets NW3.

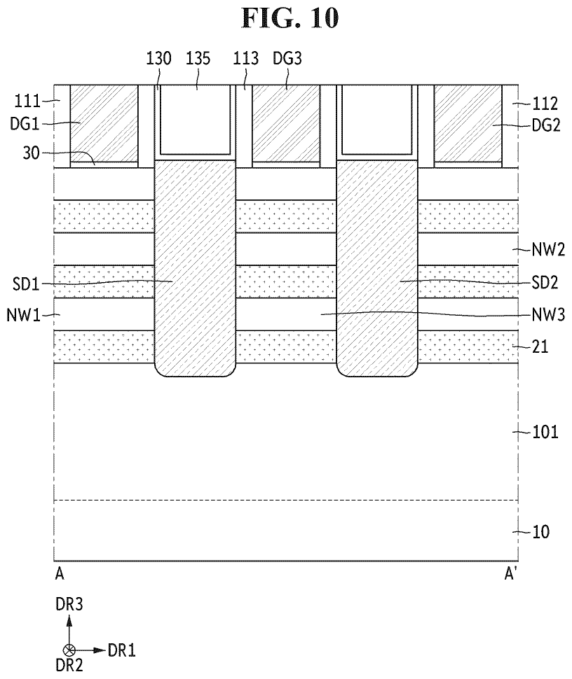

Referring to FIG. 10, a first source/drain region SD1 may be formed inside the first source/drain trench (the first source/drain trench ST1 of FIG. 9). A second source/drain region SD2 may be formed inside the second source/drain trench (the second source/drain trench ST2 of FIG. 9). For example, the first source/drain region SD1 may be in contact with the side walls of each of the first and third plurality of nanosheets NW1 and NW3 in the first horizontal direction DR1. For example, the second source/drain region SD2 may be in contact with the side walls of each of the third and second plurality of nanosheets NW3 and NW2 in the first horizontal direction DR1.

Next, a first etching stop layer 130 may be formed on the side walls of each of the exposed first, second, and third gate spacers 111, 112 and 113, the upper surfaces of each of the exposed first, second, and third dummy capping patterns (the first, second, and third dummy capping patterns DC1, DC2 and DC3 of FIG. 9), and the surfaces of each of the exposed first and second source/drain regions SD1 and SD2. Next, a first upper interlayer insulating layer 135 may be formed on the first etching stop layer 130. Next, the upper surfaces of each of the first, second, and third dummy gates DG1, DG2 and DG3 may be exposed through a planarization process.

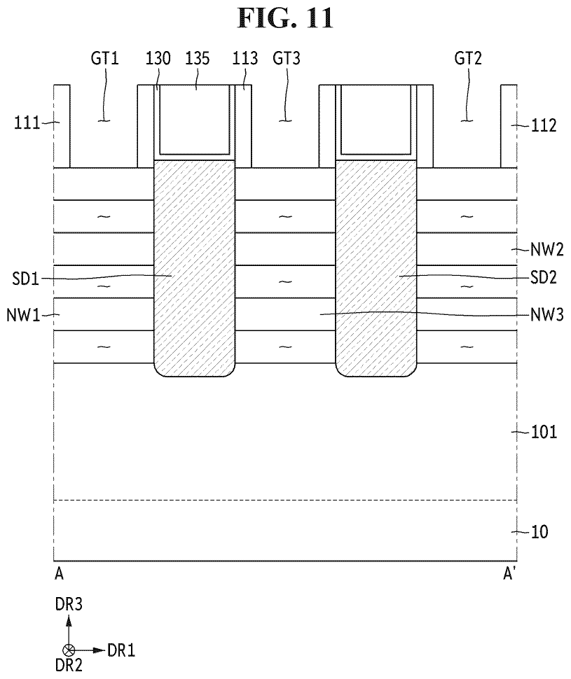

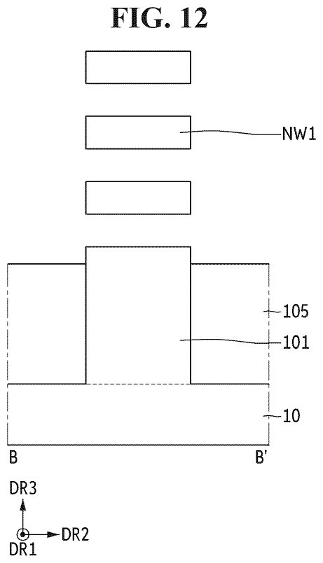

Referring to FIGS. 11 and 12, each of the first, second, and third dummy gates (the first, second, and third dummy gates DG1, DG2, and DG3 of FIG. 10), the pad oxide layer (the pad oxide layer 30 of FIG. 10), and the first semiconductor layer (the first semiconductor layer 21 of FIG. 10) may be etched. For example, the portion from which the first dummy gate (the first dummy gate DG1 of FIG. 10), the pad oxide layer (the pad oxide layer 30 of FIG. 10), and the first semiconductor layer (the first semiconductor layer 21 of FIG. 10) are removed may be defined as a first gate trench GT1. The portion from which the second dummy gate (the second dummy gate DG2 of FIG. 10), the pad oxide layer (the pad oxide layer 30 of FIG. 10), and the first semiconductor layer (the first semiconductor layer 21 of FIG. 10) are removed may be defined as a second gate trench GT2. The portion from which the third dummy gate (the third dummy gate DG3 of FIG. 10), the pad oxide layer (the pad oxide layer 30 of FIG. 10), and the first semiconductor layer (the first semiconductor layer 21 of FIG. 10) are removed may be defined as a third gate trench GT3.

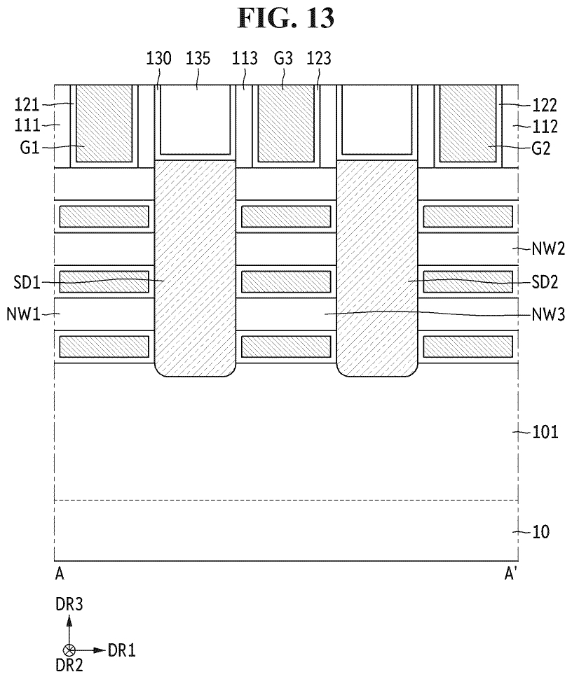

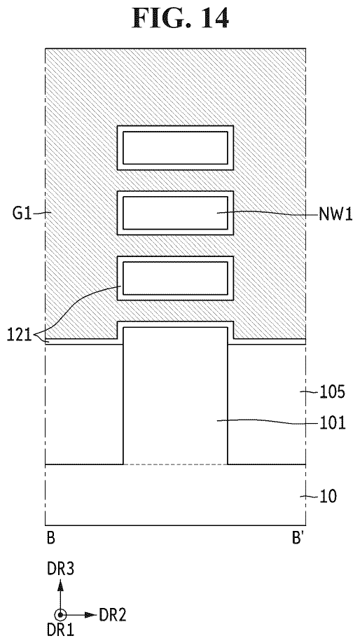

Referring to FIGS. 13 and 14, a first gate insulating layer 121 and a first gate electrode G1 may be sequentially formed inside a first gate trench (the first gate trench GT1 of FIG. 12). A second gate insulating layer 122 and a second gate electrode G2 may be sequentially formed inside a second gate trench (the second gate trench GT2 of FIG. 12). A third gate insulating layer 123 and a third gate electrode G3 may be sequentially formed inside a third gate trench (the third gate trench GT3 of FIG. 12). For example, the first gate electrode G1 may extend around (e.g., surround) the first plurality of nanosheets NW1. The second gate electrode G2 may extend around (e.g., surround) the second plurality of nanosheets NW2. The third gate electrode G3 may extend around (e.g., surround) the third plurality of nanosheets NW3. After the planarization process is performed, each of the upper surfaces of the first, second, and third gate electrodes G1, G2 and G3, the upper surfaces of the first, second, and third gate spacers 111, 112 and 113, the upper surfaces of the first, second, and third gate insulating layers 121, 122 and 123, the uppermost surface of the first etching stop layer 130, and the upper surface of the first upper interlayer insulating layer 135 may be formed on the same plane (may be coplanar with each other).

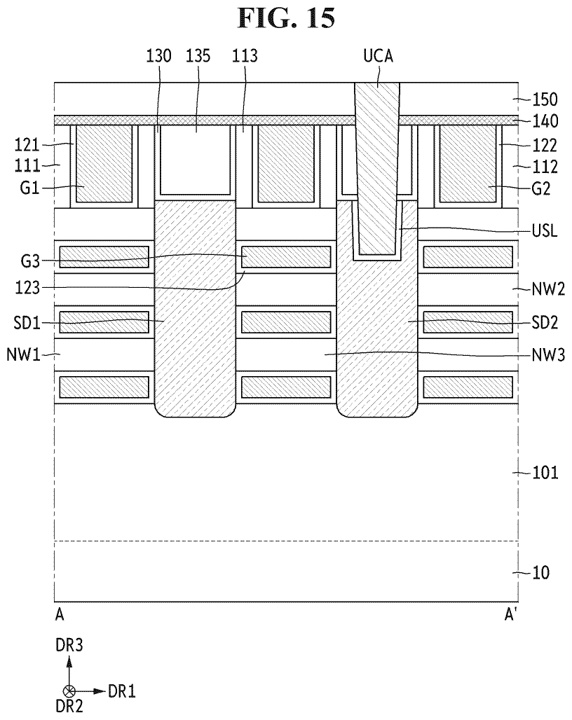

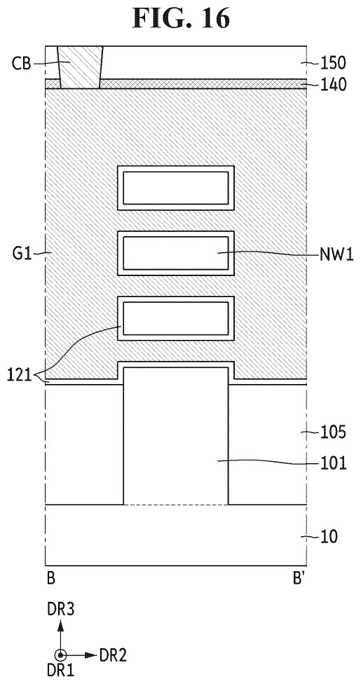

Referring to FIGS. 15 and 16, a capping layer 140 and a second upper interlayer insulating layer 150 may be sequentially formed on the upper surfaces of the first, second, and third gate electrodes G1, G2 and G3, the upper surfaces of the first, second, and third gate spacers 111, 112 and 113, the uppermost surfaces of the first, second, and third gate insulating layers 121, 122 and 123, the uppermost surface of the first etching stop layer 130, and the upper surface of the first upper interlayer insulating layer 135. Next, an upper source/drain contact UCA which extends in (e.g., penetrates) the second upper interlayer insulating layer 150, the capping layer 140, the first upper interlayer insulating layer 135, and the first etching stop layer 130 in the vertical direction DR3 and is (electrically) connected to the second source/drain region SD2 may be formed. An upper silicide layer USL may be formed along an interface between the upper source/drain contact UCA and the second source/drain region SD2. A gate contact CB which extends in (e.g., penetrates) the second upper interlayer insulating layer 150 and the capping layer 140 in the vertical direction DR3 and is (electrically) connected to the first gate electrode G1 may be formed.

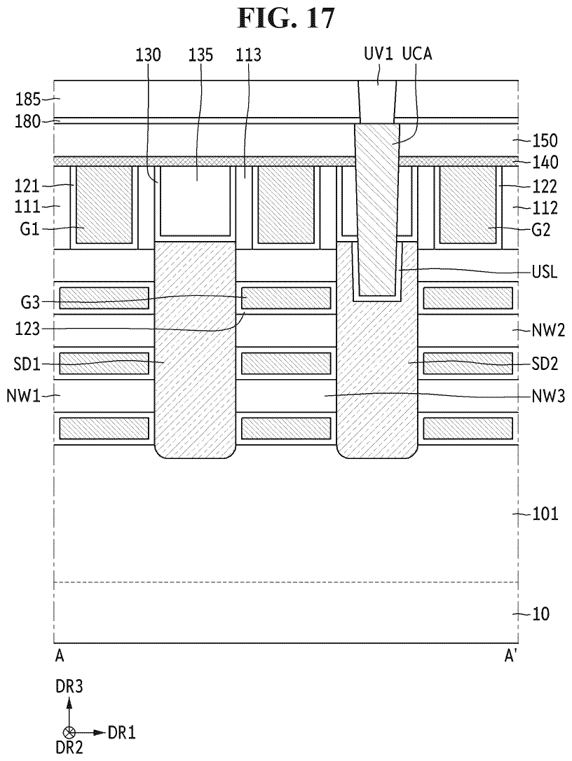

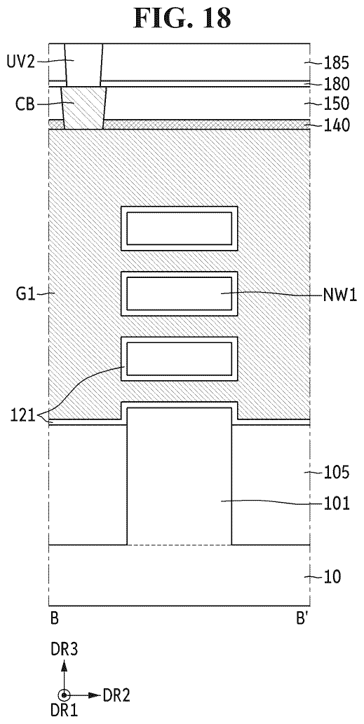

Referring to FIGS. 17 and 18, a second etching stop layer 180 and a third upper interlayer insulating layer 185 may be sequentially formed on the upper surfaces of each of the second upper interlayer insulating layer 150, the upper source/drain contact UCA, and the gate contact CB. Next, a first upper via UV1 which extends in (e.g., penetrates) the third upper interlayer insulating layer 185 and the second etching stop layer 180 in the vertical direction DR3 and is (electrically) connected to the upper source/drain contact UCA may be formed. A second upper via UV2 which extends in (e.g., penetrates) the third upper interlayer insulating layer 185 and the second etching stop layer 180 in the vertical direction DR3 and is (electrically) connected to the gate contact CB may be formed.

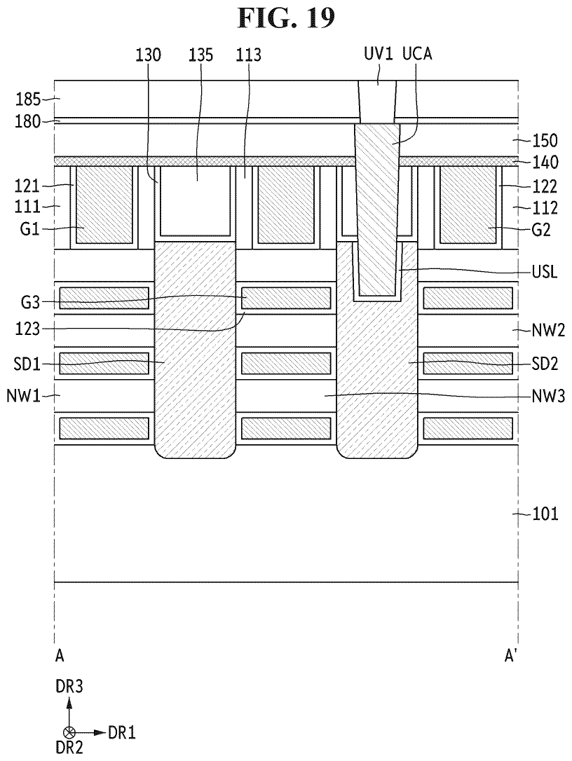

Referring to FIGS. 19 to 21, the substrate (the substrate 10 of FIGS. 17 and 18) may be etched (removed). As a result, each of the lower surface of the active pattern 101 and the lower surface of the field insulating layer 105 may be exposed.

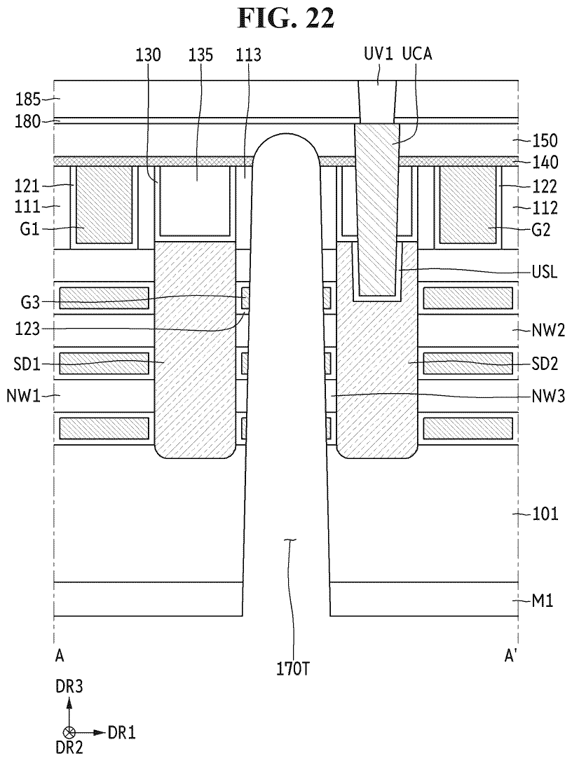

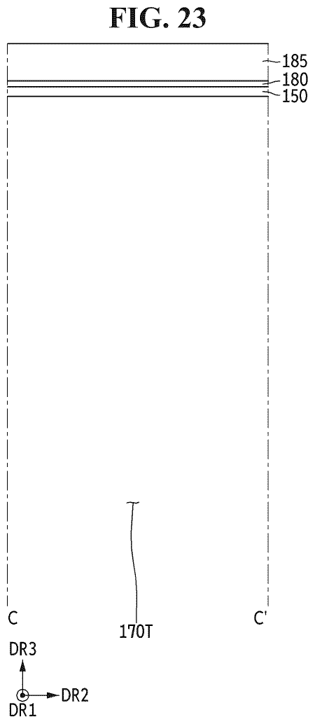

Referring to FIGS. 22 and 23, a mask pattern M1 may be formed on the lower surface of the active pattern 101. For example, the mask pattern M1 may expose a portion of the lower surface of the active pattern 101 that overlaps the third gate electrode G3 in the vertical direction DR3. Next, the active cut trench 170T may be formed (in the exposed portion of the lower surface of the active pattern 101), by performing an etching process using the mask pattern M1 as a mask. For example, the active cut trench 170T may be formed by a dry etching process.

For example, the active cut trench 170T may extend in the second horizontal direction DR2 between the third gate spacers 113 (in the first horizontal direction DR1). For example, the active cut trench 170T may extend in (e.g., penetrate) the active pattern 101, the third plurality of nanosheets NW3, the third gate electrode G3, the third gate insulating layer 123, and the capping layer 140 in the vertical direction DR3. For example, the active cut trench 170T may extend into the second upper interlayer insulating layer 150. That is, the second upper interlayer insulating layer 150 may be (at least partially) exposed through the uppermost surface of the active cut trench 170T.

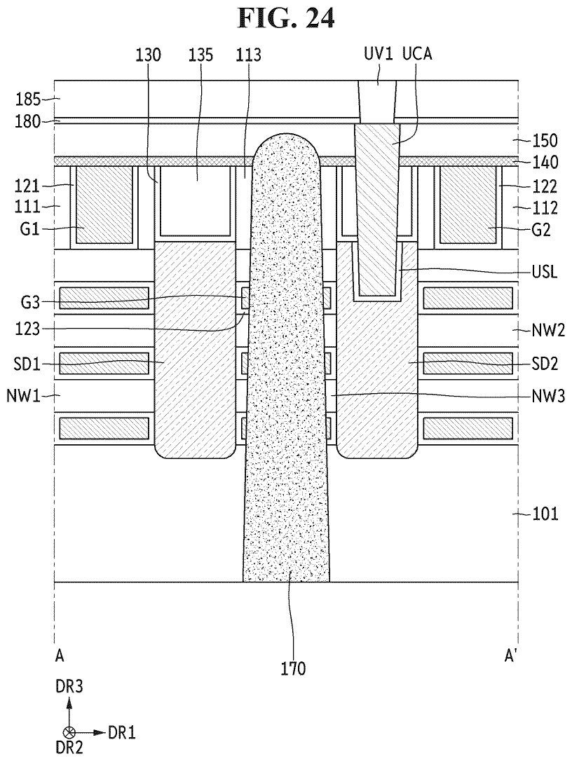

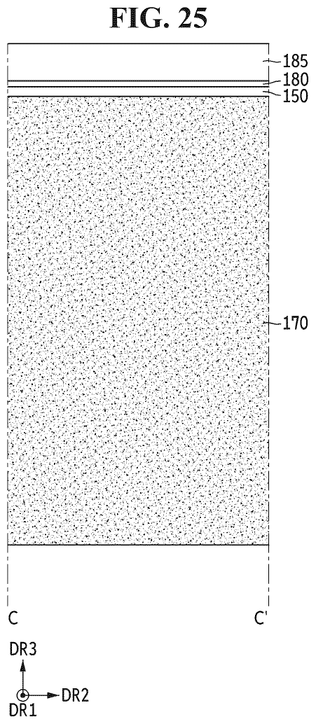

Referring to FIGS. 24 and 25, an active cut 170 may be formed inside the active cut trench (the active cut trench 170T of FIGS. 22 and 23). Next, a planarization process may be performed to etch (remove) the mask pattern (the mask pattern M1 of FIG. 22). After the planarization process is performed, the lower surface of the active pattern 101 may be exposed. Although not shown, after the planarization process is performed, the lower surface of the field insulating layer 105 may be exposed.

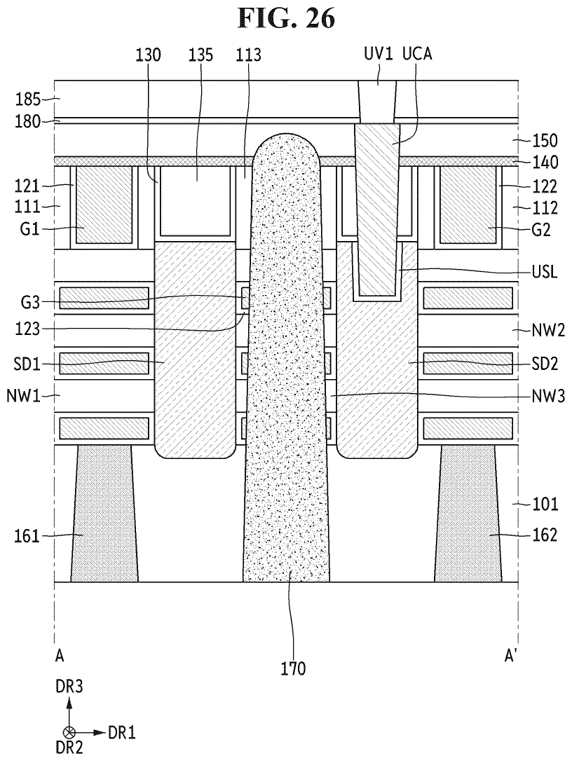

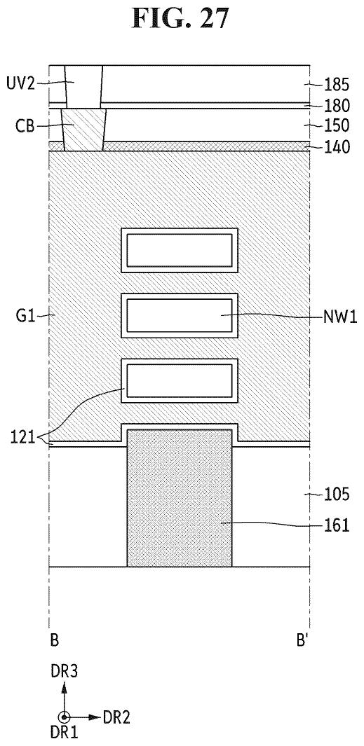

Referring to FIG. 26 and FIG. 27, a first lower separation layer 161 which extends in (e.g., penetrates) the active pattern 101 in the vertical direction DR3 below the first gate electrode G1 may be formed. A second lower separation layer 162 which extends in (e.g., penetrates) the active pattern 101 in the vertical direction DR3 below the second gate electrode G2 may be formed. For example, the first lower separation layer 161 may be in contact with the first gate insulating layer 121, and the second lower separation layer 162 may be in contact with the second gate insulating layer 122. For example, the active cut 170 may be spaced apart from the first lower separation layer 161 in the first horizontal direction DR1. The second lower separation layer 162 may be spaced apart from the active cut 170 in the first horizontal direction DR1.

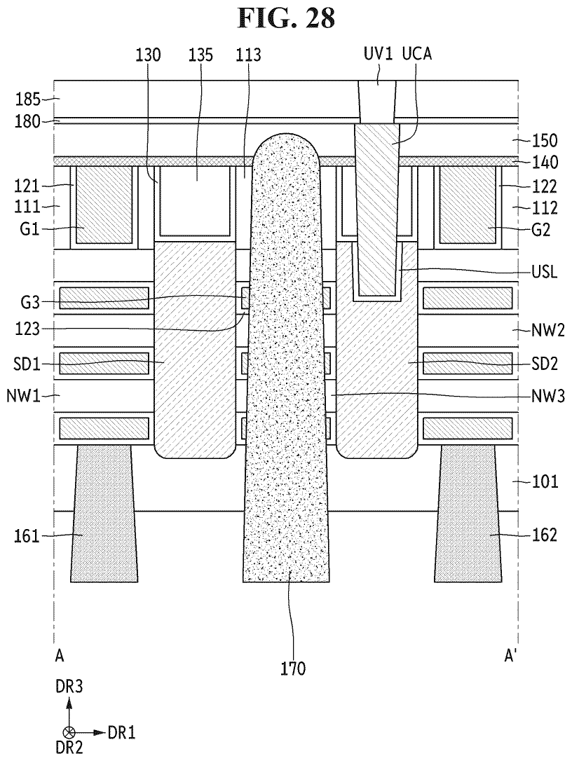

Referring to FIG. 28, a part of the active pattern 101 may be etched (removed). As a result, a part of side walls of each of the active cut 170 and the first and second lower separation layers 161 and 162 may be exposed on (below) the lower surface of the active pattern 101.

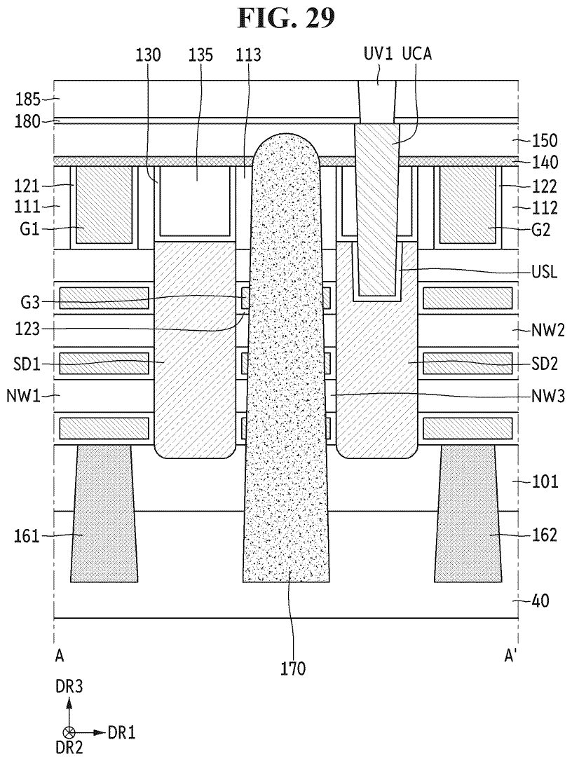

Referring to FIG. 29, a protective layer 40 may be formed on the lower surface of the active pattern 101. For example, the protective layer 40 may be on (may cover) each of the active cut 170 and the first and second lower separation layers 161 and 162 that are exposed on (below) the lower surface of the active pattern 101. For example, the protective layer 40 may include SOH (Spin-On Hardmask), but the present disclosure is not limited thereto.

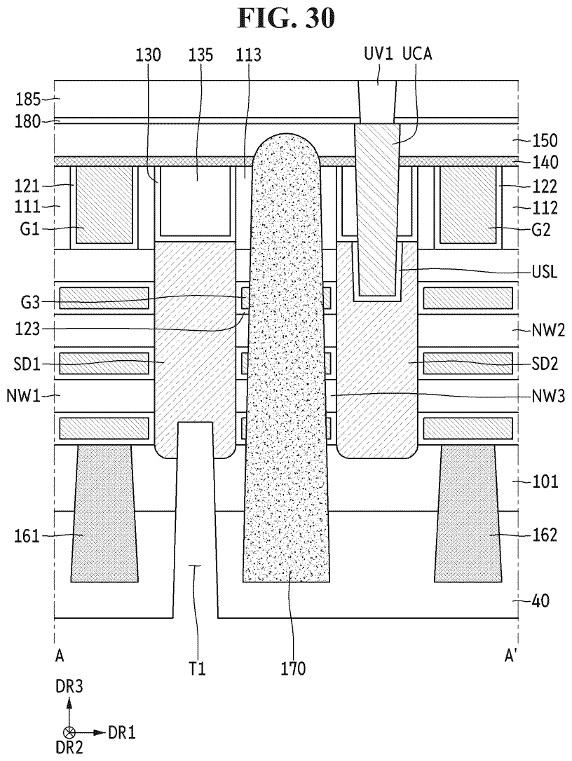

Referring to FIG. 30, a first trench T1 may be formed below the first source/drain region SD1. For example, the first trench T1 may be formed between the first lower separation layer 161 and the active cut 170 (in the first horizontal direction DR1). For example, the first trench T1 may be spaced apart from each of the first lower separation layer 161 and the active cut 170 in the first horizontal direction DR1. For example, the first trench T1 may extend in (e.g., penetrate) the protective layer 40 and the active pattern 101 in the vertical direction DR3, and may extend into the first source/drain region SD1.

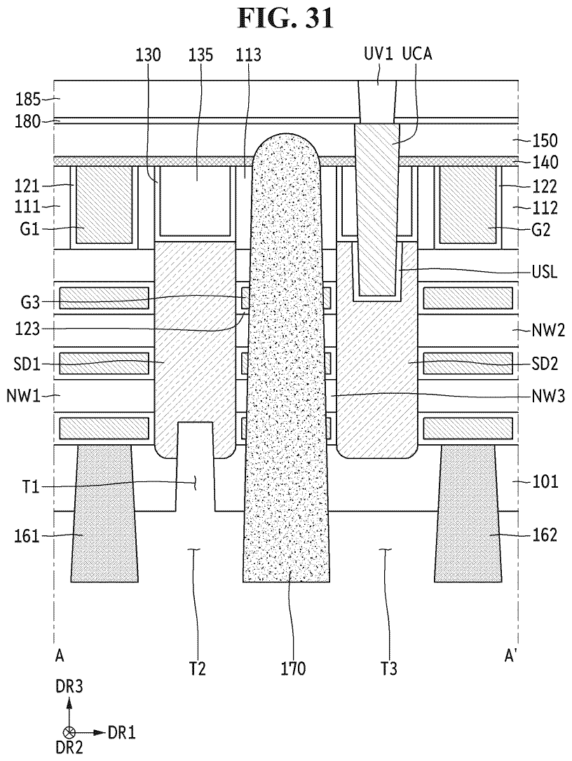

Referring to FIG. 31, the protective layer (the protective layer 40 of FIG. 30) may be etched (removed). For example, after the protective layer (the protective layer 40 of FIG. 30) is etched, the region formed between the first lower separation layer 161 and the active cut 170 on (below) the lower surface of the active pattern 101 may be defined as a second trench T2. The second trench T2 may be formed below the first trench T1. After the protective layer (the protective layer 40 of FIG. 30) is etched, the region formed between the active cut 170 and the second lower separation layer 162 on (below) the lower surface of the active pattern 101 may be defined as a third trench T3.

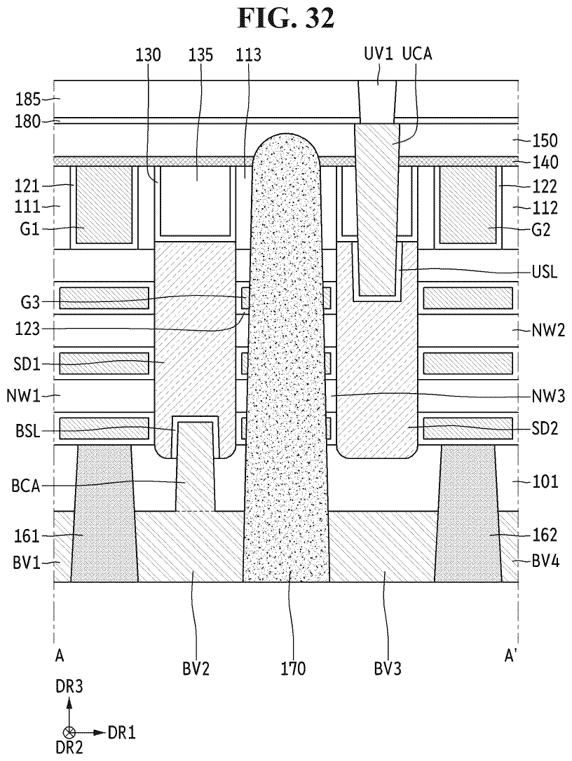

Referring to FIG. 32, a conductive material may be (at least partially) filled into each of the first, second, and third trenches (the first, second, and third trenches T1, T2, and T3 of FIG. 31). For example, the conductive material filled into the first trench (the first trench T1 of FIG. 31) may be defined as a lower source/drain contact BCA. The conductive material filled into the second trench (the second trench T2 of FIG. 31) may be defined as a second lower via BV2. The conductive material filled into the third trench (the third trench T3 of FIG. 31) may be defined as a third lower via BV3. Next, the planarization process may be performed to expose the lower surfaces of each of the active cut 170 and the first and second lower separation layers 161 and 162.

Referring to FIGS. 2 to 4, a lower interlayer insulating layer 100 may be formed on the lower surfaces of each of the active cut 170, the first and second lower separation layers 161 and 162, and the first, second, third, and fourth lower vias BV1, BV2, BV3, and BV4. The semiconductor device shown in FIGS. 2 to 4 may be fabricated through such a fabricating process.

In the method for fabricating the semiconductor device according to some embodiments of the present disclosure, the active cut 170 may be formed in the vertical direction DR3 from the lower surface of the active pattern 101 (or from the upper surface of the lower interlayer insulating layer 100). Therefore, the method for fabricating the semiconductor device according to some embodiments of the present disclosure may reduce the process difficulty compared to a case where the active cut 170 is formed by penetrating the capping layer 140 from the upper part of the third gate electrode G3 in the vertical direction DR3. Furthermore, the method for fabricating the semiconductor device according to some embodiments of the present disclosure may form the active cut 170 to penetrate the capping layer 140 in the vertical direction DR3. That is, the uppermost surface of the active cut 170 may be formed to be higher than the upper surface of the capping layer 140. Therefore, the method for fabricating the semiconductor device according to some embodiments of the present disclosure may improve the reliability of the active cut 170.

In the semiconductor device according to some embodiments of the present disclosure fabricated by the above fabricating method, the active cut 170 may be formed to extend in (e.g., penetrate) the third plurality of nanosheets NW3, the third gate electrode G3, the third gate insulating layer 123, and the capping layer 140 in the vertical direction DR3. That is, the uppermost surface of the active cut 170 may be formed to be higher than the uppermost surface of the capping layer 140. A width of the lower surface of the active cut 170 (in the first horizontal direction DR1) may be formed to be greater than a width of the upper surface of the active cut 170 (in the first horizontal direction DR1). Both side walls (e.g., opposite side walls) of the active cut 170 in the first horizontal direction DR1 may be in contact with each of the active pattern 101, the second lower via BV2, and the third lower via BV3.

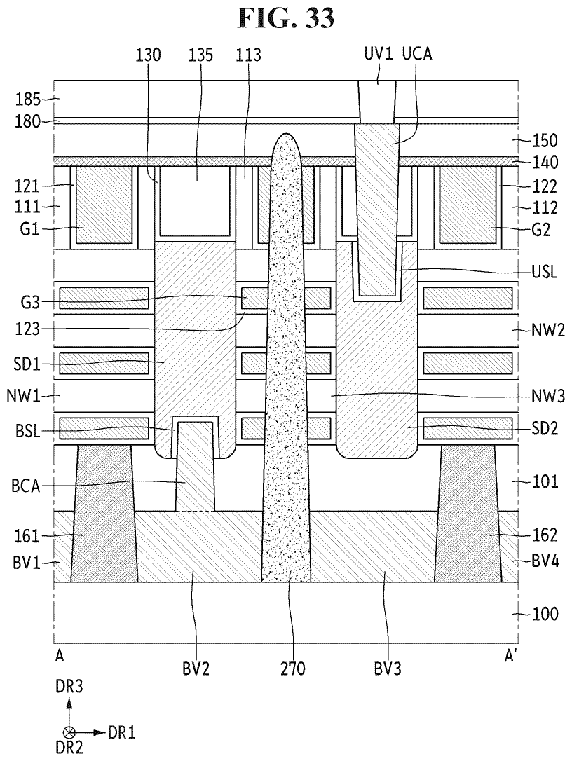

Hereinafter, a semiconductor device according to some embodiments of the present disclosure will be described referring to FIG. 33. Differences from the semiconductor device shown in FIGS. 1 to 4 will be mainly described.

FIG. 33 is a cross-sectional view for describing a semiconductor device according to some embodiments of the present disclosure.

Referring to FIG. 33, in the semiconductor device according to some embodiments of the present disclosure, an active cut 270 may be spaced apart from the third gate spacer 113 in the first horizontal direction DR1.

For example, a third gate insulating layer 123 and a third gate electrode G3 may be disposed between the third gate spacer 113 and the active cut 270 (in the first horizontal direction DR1). For example, the third gate electrode G3 may be disposed between both side walls (e.g., opposite side walls) of the active cut 270 in the first horizontal direction DR1 and the third gate insulating layer 123, on the upper surface of the uppermost nanosheet of the third plurality of nanosheets NW3. For example, on the upper surface of the uppermost nanosheet of the third plurality of nanosheets NW3, both side walls (e.g., opposite side walls) of the active cut 270 in the first horizontal direction DR1 may be in contact with each of the third gate insulating layer 123 and the third gate electrode G3.

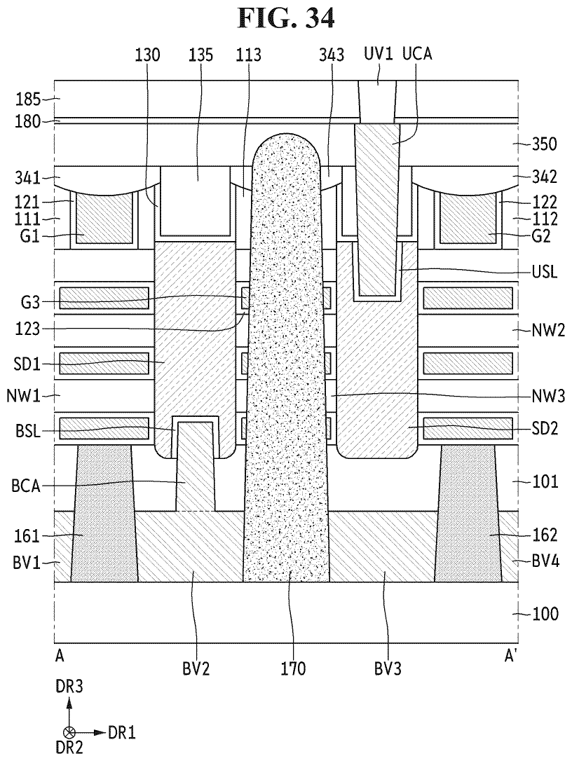

Hereinafter, a semiconductor device according to some embodiments of the present disclosure will be described referring to FIG. 34. Differences from the semiconductor device shown in FIGS. 1 to 4 will be mainly described.

FIG. 34 is a cross-sectional view for describing a semiconductor device according to some embodiments of the present disclosure.

Referring to FIG. 34, in the semiconductor device according to some embodiments of the present disclosure, the capping layer (corresponding to the capping layer 140 in FIGS. 2 and 3) may include first, second, and third capping layers 341, 342, and 343 which are spaced apart from each other in the first horizontal direction DR1. The first, second, and third capping layer 341, 342, and 343 may be referred to as sub-capping layers of the capping layer.

For example, a first capping layer 341 may be in contact with each of the upper surface of the first gate electrode G1, the upper surface of the first gate spacer 111, the uppermost surface of the first gate insulating layer 121, and the uppermost surface of the first etching stop layer 130. For example, a second capping layer 342 may be in contact with each of the upper surface of the second gate electrode G2, the upper surface of the second gate spacer 112, the uppermost surface of the second gate insulating layer 122, and the uppermost surface of the first etching stop layer 130. The second capping layer 342 may be spaced apart from the first capping layer 341 in the first horizontal direction DR1. For example, a third capping layer 343 may be in contact with each of the upper surface of the third gate spacer 113 and the uppermost surface of the first etching stop layer 130. The third capping layer 343 may be disposed between the first capping layer 341 and the second capping layer 342 (in the first horizontal direction DR1). The third capping layer 343 may be spaced apart from each of the first capping layer 341 and the second capping layer 342 in the first horizontal direction DR1.

For example, the first upper interlayer insulating layer 135 may be in contact with side walls of each of the first, second, and third capping layers 341, 342, and 343 in the first horizontal direction DR1. For example, the upper surfaces of each of the first, second, and third capping layers 341, 342, and 343 may be formed on the same plane as (may be coplanar with) the upper surface of the first upper interlayer insulating layer 135. For example, the upper surface of the first upper interlayer insulating layer 135 may be in contact with the second upper interlayer insulating layer 350. For example, the active cut 170 may extend in (e.g., penetrate) the third capping layer 343 in the vertical direction DR3, and extend into the second upper interlayer insulating layer 350. That is, the uppermost surface of the active cut 170 may be formed to be higher than the upper surface of the third capping layer 343. For example, both side walls (e.g., opposite side walls) of the active cut 170 in the first horizontal direction DR1 may be in contact with the third capping layer 343. For example, the upper surface of the upper source/drain contact UCA may be formed to be higher than the uppermost surface of the active cut 170.

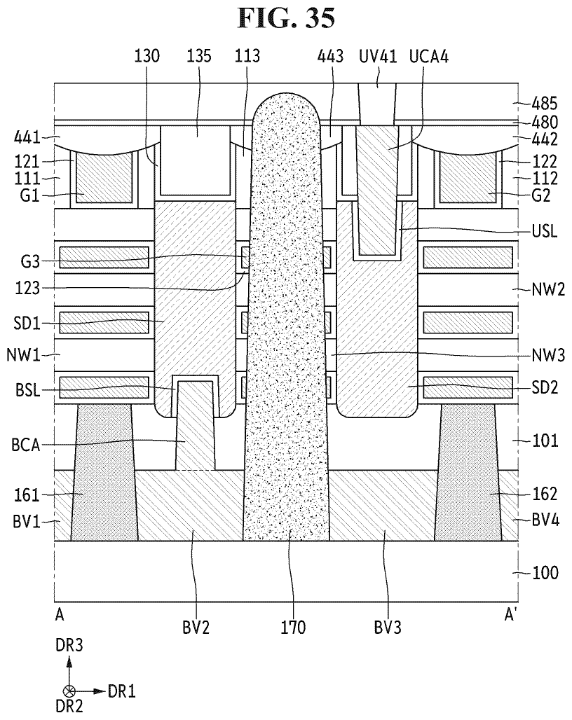

Hereinafter, a semiconductor device according to some embodiments of the present disclosure will be described referring to FIG. 35. Differences from the semiconductor device shown in FIGS. 1 to 4 will be mainly described.

FIG. 35 is a cross-sectional view for describing a semiconductor device according to some embodiments of the present disclosure.

Referring to FIG. 35, in the semiconductor device according to some embodiments of the present disclosure, the capping layer (corresponding to the capping layer 140 in FIGS. 2 and 3) may include first, second, and third capping layers 441, 442, and 443 spaced apart from each other in the first horizontal direction DR1. The first, second, and third capping layer 441, 442, and 443 may be referred to as sub-capping layers of the capping layer.

For example, a first capping layer 441 may be in contact with each of the upper surface of the first gate electrode G1, the upper surface of the first gate spacer 111, the uppermost surface of the first gate insulating layer 121, and the uppermost surface of the first etching stop layer 130. For example, a second capping layer 442 may be in contact with each of the upper surface of the second gate electrode G2, the upper surface of the second gate spacer 112, the uppermost surface of the second gate insulating layer 122, and the uppermost surface of the first etching stop layer 130. The second capping layer 442 may be spaced apart from the first capping layer 441 in the first horizontal direction DR1. For example, a third capping layer 443 may be in contact with each of the upper surface of the third gate spacer 113 and the uppermost surface of the first etching stop layer 130. The third capping layer 443 may be disposed between the first capping layer 441 and the second capping layer 442 (in the first horizontal direction DR1). The third capping layer 443 may be spaced apart from each of the first capping layer 441 and the second capping layer 442 in the first horizontal direction DR1.

For example, the first upper interlayer insulating layer 135 may be in contact with the side walls of each of the first, second, and third capping layers 441, 442, and 443 in the first horizontal direction DR1. For example, the upper surfaces of each of the first, second, and third capping layers 441, 442, and 443 may be formed on the same plane as (may be coplanar with) the upper surface of the first upper interlayer insulating layer 135. For example, the second etching stop layer 480 may be disposed on the upper surfaces of each of the first, second, and third capping layers 441, 442, and 443, the first upper interlayer insulating layer 135, and an upper source/drain contact UCA4. A third upper interlayer insulating layer 485 may be disposed on the upper surface of the second etching stop layer 480. For example, the active cut 170 may extend in (e.g., penetrate) the third capping layer 443 and the second etching stop layer 480 in the vertical direction DR3, and extend into the third upper interlayer insulating layer 485. That is, the uppermost surface of the active cut 170 may be formed to be higher than the upper surface of the third capping layer 443. For example, both side walls (e.g., opposite side walls) of the active cut 170 in the first horizontal direction DR1 may be in contact with the third capping layer 443.

For example, the upper source/drain contact UCA4 may extend in (e.g., penetrate) the first upper interlayer insulating layer 135 and the first etching stop layer 130 in the vertical direction DR3, and may by be (electrically) connected to the second source/drain region SD2. For example, the upper surface of the upper source/drain contact UCA4 may be formed on the same plane as (may be coplanar with) the upper surfaces of each of the first upper interlayer insulating layer 135 and the first, second, and third capping layers 441, 442, and 443. For example, the uppermost surface of the active cut 170 may be formed to be higher than the upper surface of the upper source/drain contact UCA4. For example, the first upper via UV41 may extend in (e.g., penetrate) the third upper interlayer insulating layer 485 and the second etching stop layer 480 in the vertical direction DR3, and may be (electrically) connected to the upper source/drain contact UCA4.

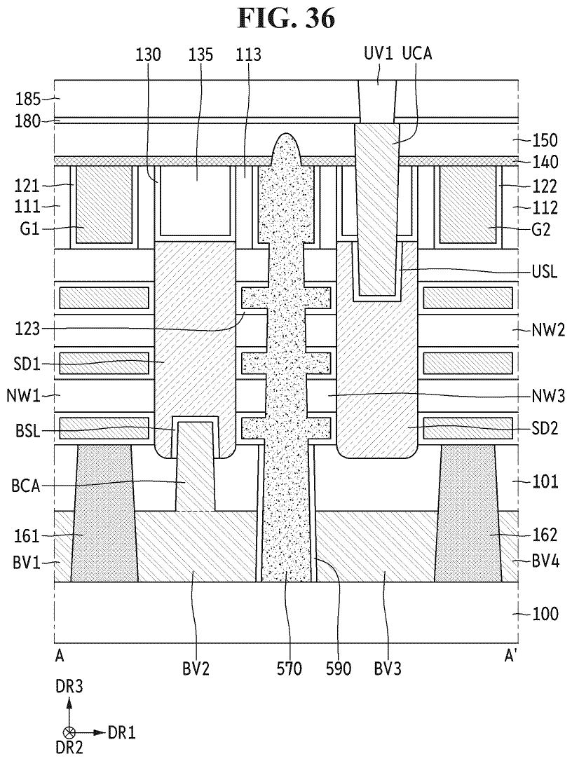

Hereinafter, a semiconductor device according to some embodiments of the present disclosure will be described referring to FIG. 36. Differences from the semiconductor device shown in FIGS. 1 to 4 will be mainly described.

FIG. 36 is a cross-sectional view for describing a semiconductor device according to some embodiments of the present disclosure.

Referring to FIG. 36, in the semiconductor device according to some embodiments of the present disclosure, at least a part of the active cut 570 may be disposed between adjacent third plurality of nanosheets NW3.

For example, at least a part of an active cut 570 may be disposed between the upper surface of the active pattern 101 and the lower surface of the lowermost nanosheet of the third plurality of nanosheets NW3 (in the vertical direction DR3). Between the upper surface of the active pattern 101 and the lower surface of the lowermost nanosheet of the third plurality of nanosheets NW3, the active cut 570 may be in contact with the third gate insulating layer 123. In some embodiments, between adjacent third plurality of nanosheets NW3, the active cut 570 may be in contact with the third gate insulating layer 123. For example, the third gate insulating layer 123 may be disposed between the third gate spacer 113 and the active cut 570. For example, on the upper surface of the uppermost nanosheet of the third plurality of nanosheets NW3, both side walls (e.g., opposite side walls) of the active cut 570 in the first horizontal direction DR1 may be in contact with the third gate insulating layer 123.

For example, an insulating liner layer 590 may be disposed between both side walls (e.g., opposite side walls) of the active cut 570 in the first horizontal direction DR1 and the second and third lower vias BV2 and BV3. The insulating liner layer 590 may be disposed between both side walls (e.g., opposite side walls) of the active cut 570 in the first horizontal direction DR1 and the active pattern 101. For example, a lower surface of the insulating liner layer 590 may be formed on the same plane as (may be coplanar with) the lower surface of the active cut 570. For example, the insulating liner layer 590 may be formed conformally. The insulating liner layer 590 may include an insulating material. For example, the insulating liner layer 590 may include silicon nitride (SiN), silicon oxynitride (SiON), silicon carbonitride (SiCN), silicon oxide (SiO₂), silicon oxycarbonitride (SiOCN), silicon boronitride (SiBN), silicon oxyboronitride (SiOBN), silicon oxycarbide (SiOC), and/or combinations thereof. However, the present disclosure is not limited thereto.

Hereinafter, a method for fabricating a semiconductor device according to some embodiments of the present disclosure will be described referring to FIGS. 36 to 41. Differences from the method for fabricating the semiconductor device shown in FIGS. 5 to 32 will be mainly described.

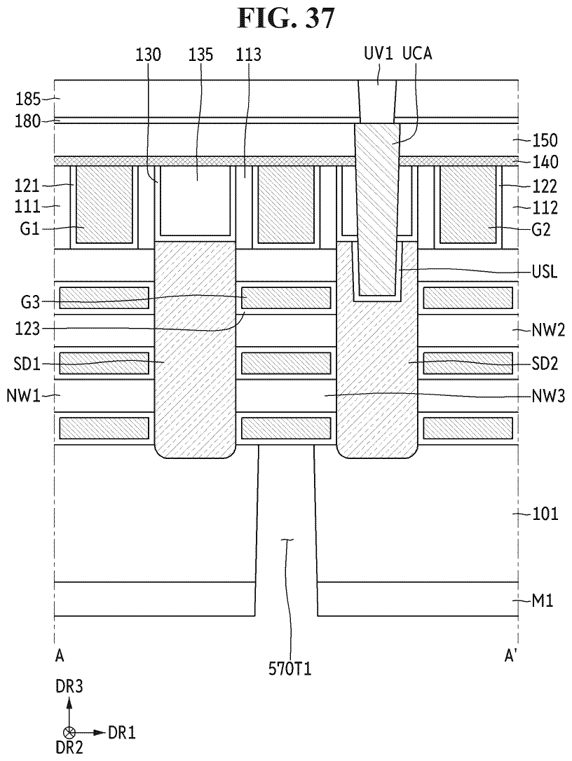

FIGS. 37 to 41 are intermediate step diagrams for describing a method for fabricating a semiconductor device according to some embodiments of the present disclosure.

Referring to FIG. 37, after performing the fabricating process shown in FIGS. 5 to 21, a mask pattern M1 may be formed on the lower surface of the active pattern 101. For example, the mask pattern M1 may expose a portion of the lower surface of the active pattern 101 that overlaps the third gate electrode G3 in the vertical direction DR3. Then, an etching process using the mask pattern M1 as a mask may be performed to form a first active cut trench 570T1. For example, the first active cut trench 570T1 may be formed by a dry etching process.

For example, the first active cut trench 570T1 may extend in the second horizontal direction DR2 below the third gate electrode G3. For example, the first active cut trench 570T1 may extend in (e.g., penetrate) the active pattern 101 in the vertical direction DR3. For example, the third gate insulating layer 123 may be exposed through the first active cut trench 570T1.

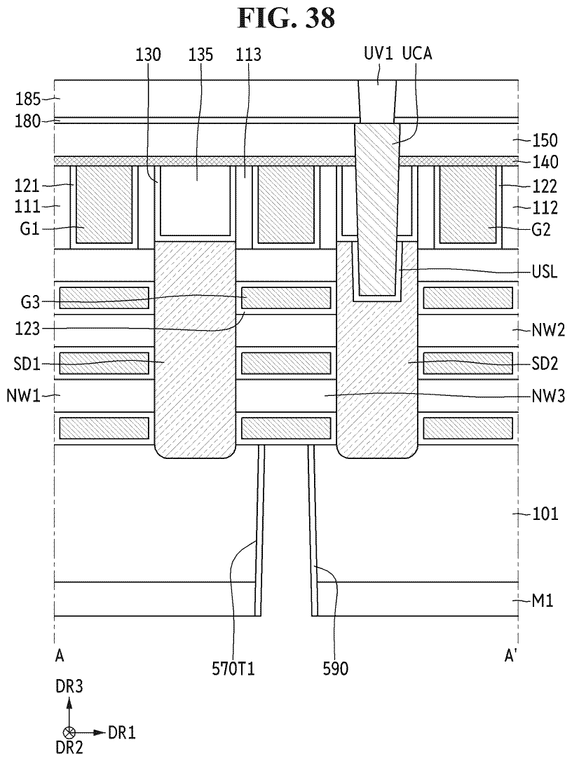

Referring to FIG. 38, an insulating liner layer 590 may be formed on a side wall of the first active cut trench 570T1. For example, the insulating liner layer 590 may be formed conformally. After forming the insulating liner layer 590, the third gate insulating layer 123 may be exposed through the first active cut trench 570T1.

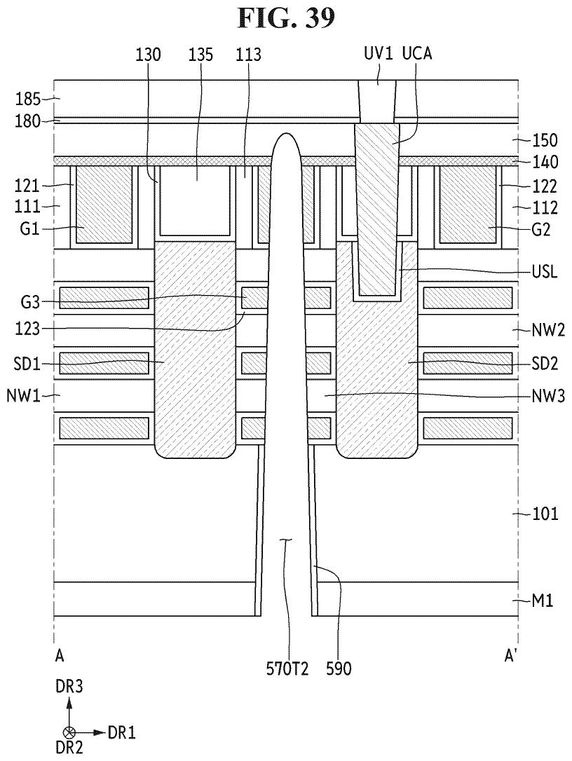

Referring to FIG. 39, an etching process of using the mask pattern M1 and the insulating liner layer 590 as a mask may be performed to form a second active cut trench 570T2. For example, the second active cut trench 570T2 may be formed by performing a dry etching process through the first active cut trench (the first active cut trench 570T1 of FIG. 38). For example, the second active cut trench 570T2 may extend in (e.g., penetrate) the active pattern 101, the third plurality of nanosheets NW3, the third gate electrode G3, the third gate insulating layer 123, and the capping layer 140 in the vertical direction DR3. For example, the second active cut trench 570T2 may extend into the second upper interlayer insulating layer 150. That is, the second upper interlayer insulating layer 150 may be (at least partially) exposed through the uppermost surface of the second active cut trench 570T2. For example, the third gate electrode G3 may be exposed through the second active cut trench 570T2 on the uppermost surface of the uppermost nanosheet of the third plurality of nanosheets NW3.

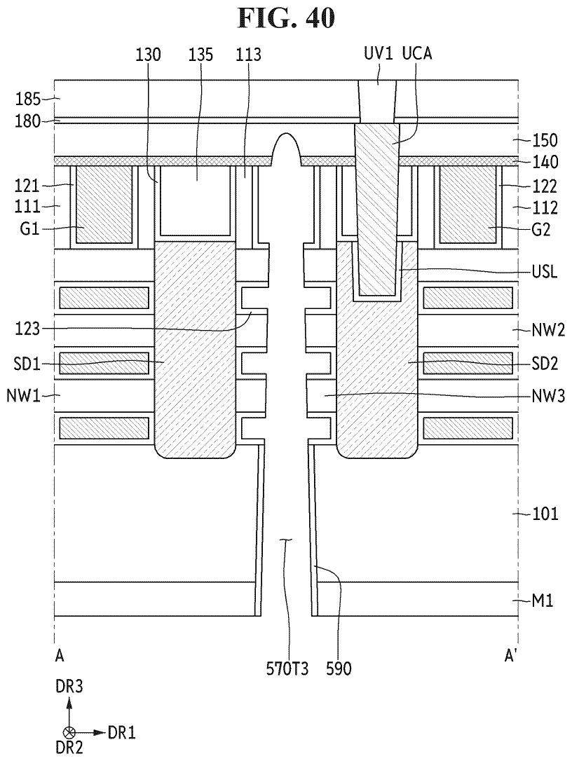

Referring to FIG. 40, a wet etching process may be performed to etch the third gate electrode (e.g., the third gate electrode G3 of FIG. 39) through the second active cut trench (e.g., the second active cut trench 570T2 of FIG. 39). After the third gate electrode (e.g., the third gate electrode G3 of FIG. 39) is etched, the region in which the etched portion of the third gate electrode (e.g., the third gate electrode G3 of FIG. 39) and the second active cut trench (e.g., the second active cut trench 570T2 of FIG. 39) may be collectively defined as a third active cut trench 570T3.

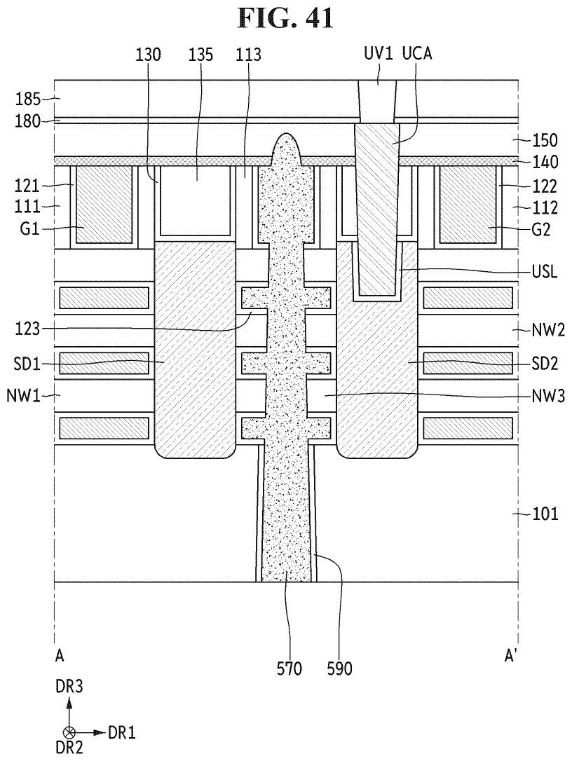

Referring to FIG. 41, an active cut 570 may be formed inside the third active cut trench (e.g., the third active cut trench 570T3 of FIG. 40). Next, the planarization process may be performed to etch the mask pattern (e.g., the mask pattern M1 of FIG. 40) and a part of the insulating liner layer 590. After the planarization process is performed, the lower surface of the active pattern 101 may be exposed. Next, the fabricating process shown in FIGS. 26 to 32 may be performed.

Referring to FIG. 36, a lower interlayer insulating layer 100 may be formed on the lower surfaces of each of the active cut 570, the insulating liner layer 590, the first and second lower separation layers 161 and 162, and the first, second, third, and fourth lower vias BV1 to BV4. The semiconductor device shown in FIG. 36 may be fabricated through such a fabricating process.

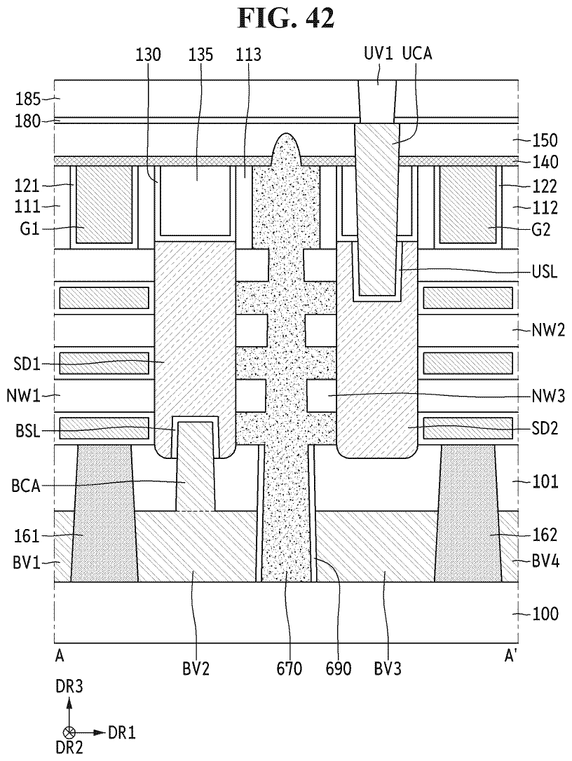

Hereinafter, a semiconductor device according to some embodiments of the present disclosure will be described referring to FIG. 42. Differences from the semiconductor device shown in FIGS. 1 to 4 will be mainly described.

FIG. 42 is a cross-sectional view for explaining a semiconductor device according to some embodiments of the present disclosure.

Referring to FIG. 42, in a semiconductor device according to some embodiments of the present disclosure, at least a part of an active cut 670 may be disposed between adjacent the third plurality of nanosheets NW3.

For example, at least a part of the active cut 670 may be disposed between the upper surface of the active pattern 101 and the lower surface of the lowermost nanosheet of the third plurality of nanosheets NW3 (in the vertical direction DR3). Between the upper surface of the active pattern 101 and the lower surface of the lowermost nanosheet of the third plurality of nanosheets NW3, the active cut 670 may be in contact with each of the first and second source/drain regions SD1 and SD2. Between adjacent the third plurality of nanosheets NW3, the active cut 670 may be in contact with each of the first and second source/drain regions SD1 and SD2. For example, on the upper surface of the uppermost nanosheet of the third plurality of nanosheets NW3, both side walls (e.g., opposite side walls) of the active cut 670 in the first horizontal direction DR1 may be in contact with the third gate spacer 113.

For example, an insulating liner layer 690 may be disposed between both side walls (e.g., opposite side walls) of the active cut 670 in the first horizontal direction DR1 and each of the second and third lower vias BV2 and BV3. The insulating liner layer 690 may be disposed between both side walls (e.g., opposite side walls) of the active cut 670 in the first horizontal direction DR1 and the active pattern 101. For example, a lower surface of the insulating liner layer 690 may be formed on the same plane as (may be coplanar with) a lower surface of the active cut 670. For example, the insulating liner layer 690 may be formed conformally. The insulating liner layer 690 may include an insulating material.

Although the embodiments of the present disclosure have been described above with reference to the accompanying drawings, the present disclosure is not limited to the above embodiments, and may be fabricated in various different forms. Those skilled in the art will appreciate that the present disclosure may be embodied in other specific forms without changing the essential features of the present disclosure. Accordingly, the above-described embodiments should be understood in all respects as illustrative and not restrictive.

What is claimed is:

1. A semiconductor device comprising:
a lower interlayer insulating layer;
an active pattern on an upper surface of the lower interlayer insulating layer, wherein the active pattern extends in a first horizontal direction that is parallel with the upper surface of the lower interlayer insulating layer, and wherein the active pattern is spaced apart from the upper surface of the lower interlayer insulating layer in a vertical direction that is perpendicular to the upper surface of the lower interlayer insulating layer;
a first plurality of nanosheets on the active pattern, wherein first nanosheets of the first plurality of nanosheets are spaced apart from each other in the vertical direction;
a second plurality of nanosheets on the active pattern, wherein second nanosheets of the second plurality of nanosheets are spaced apart from each other in the vertical direction, and wherein the second plurality of nanosheets is spaced apart from the first plurality of nanosheets in the first horizontal direction;
a first gate electrode on the active pattern, wherein the first gate electrode extends in a second horizontal direction that is parallel with the upper surface of the lower interlayer insulating layer and intersects the first horizontal direction, and wherein the first gate electrode extends around the first plurality of nanosheets;
a capping layer on an upper surface of the first gate electrode; and
an active cut on the upper surface of the lower interlayer insulating layer, wherein the active cut extends in the second horizontal direction and is spaced apart from the first gate electrode in the first horizontal direction,
wherein the active cut extends into the active pattern and the second plurality of nanosheets in the vertical direction,
wherein an uppermost surface of the active cut is farther than an upper surface of the capping layer from the upper surface of the lower interlayer insulating layer in the vertical direction, and
wherein side walls of the active cut are in contact with the second plurality of nanosheets.

2. The semiconductor device of claim 1, further comprising:
a lower separation layer on the upper surface of the lower interlayer insulating layer,
wherein the lower separation layer extends into the active pattern in the vertical direction, and
wherein the lower separation layer overlaps the first gate electrode in the vertical direction.

3. The semiconductor device of claim 2, wherein the active cut is spaced apart from the lower separation layer in the first horizontal direction, and
wherein a lower surface of the active cut is coplanar with a lower surface of the lower separation layer.

4. The semiconductor device of claim 1, further comprising:
a lower via between the upper surface of the lower interlayer insulating layer and a lower surface of the active pattern,
wherein the lower via is in contact with at least one of the side walls of the active cut.

5. The semiconductor device of claim 1, further comprising:
a source/drain region between the first plurality of nanosheets and the second plurality of nanosheets on the active pattern; and
a lower source/drain contact that extends into the active pattern in the vertical direction,
wherein the lower source/drain contact is electrically connected to the source/drain region, and
wherein the active cut is spaced apart from the lower source/drain contact by the active pattern in the first horizontal direction.

6. The semiconductor device of claim 1, further comprising:
a first gate spacer on an upper surface of an uppermost first nanosheet from among the first nanosheets, wherein the first gate spacer is on side walls of the first gate electrode; and
a second gate spacer on an upper surface of an uppermost second nanosheet from among the second nanosheets, wherein the second gate spacer is on the side walls of the active cut,
wherein an upper surface of each of the first gate spacer and the second gate spacer is in contact with a lower surface of the capping layer, and
wherein the active cut extends into the capping layer in the vertical direction.

7. The semiconductor device of claim 6, further comprising:
an upper interlayer insulating layer that extends around side walls of each of the first gate spacer and the second gate spacer,
wherein an upper surface of the upper interlayer insulating layer is in contact with the lower surface of the capping layer.

8. The semiconductor device of claim 6, further comprising:
a gate insulating layer between the side walls of the active cut and the second gate spacer.

9. The semiconductor device of claim 1, wherein a width of a lower surface of the active cut in the first horizontal direction is greater than a width of an upper surface of the active cut in the first horizontal direction.

10. The semiconductor device of claim 1, wherein the capping layer includes a first sub capping layer that is in contact with the upper surface of the first gate electrode; and
a second sub capping layer that is in contact with the side walls of the active cut,
wherein the second sub capping layer is spaced apart from the first sub capping layer in the first horizontal direction,
wherein the active cut extends into the second sub capping layer in the vertical direction, and
wherein the uppermost surface of the active cut is farther than an upper surface of the second sub capping layer from the upper surface of the lower interlayer insulating layer in the vertical direction.

11. The semiconductor device of claim 1, further comprising:
a second gate electrode on the active pattern,
wherein the second gate electrode extends in the second horizontal direction and is spaced apart from the first gate electrode in the first horizontal direction,
wherein the second gate electrode extends around the second plurality of nanosheets, and
wherein the second gate electrode is in contact with the side walls of the active cut.

12. The semiconductor device of claim 1, wherein at least a portion of the active cut is between adjacent ones of the second nanosheets in the vertical direction.

13. A semiconductor device comprising:
a lower interlayer insulating layer;
an active pattern on an upper surface of the lower interlayer insulating layer, wherein the active pattern extends in a first horizontal direction that is parallel with the upper surface of the lower interlayer insulating layer, and wherein the active pattern is spaced apart from the upper surface of the lower interlayer insulating layer in a vertical direction that is perpendicular to the upper surface of the lower interlayer insulating layer;
a first gate electrode on the active pattern, wherein the first gate electrode extends in a second horizontal direction that is parallel with the upper surface of the lower interlayer insulating layer and intersects the first horizontal direction;
a second gate electrode on the active pattern, wherein the second gate electrode extends in the second horizontal direction and is spaced apart from the first gate electrode in the first horizontal direction;
an active cut on the upper surface of the lower interlayer insulating layer, wherein the active cut extends in the second horizontal direction between the first gate electrode and the second gate electrode in the first horizontal direction, and wherein the active cut is spaced apart from each of the first gate electrode and the second gate electrode in the first horizontal direction;
a first gate spacer on side walls of the first gate electrode;
a second gate spacer on side walls of the second gate electrode;
a third gate spacer on side walls of the active cut; and
a capping layer that is in contact with upper surfaces of the first gate electrode and the second gate electrode and upper surfaces of the first gate spacer, the second gate spacer, and the third gate spacer,
wherein the active cut extends into the active pattern and the capping layer in the vertical direction, and
wherein an uppermost surface of the active cut is farther than an upper surface of the capping layer from the upper surface of the lower interlayer insulating layer in the vertical direction.

14. The semiconductor device of claim 13, further comprising:
nanosheets on the active pattern,
wherein the nanosheets are spaced apart from each other in the vertical direction,
wherein the nanosheets are between the first gate electrode and the second gate electrode in the first horizontal direction, and
wherein the nanosheets are in contact with the side walls of the active cut.

15. The semiconductor device of claim 13, further comprising:
a lower via between the upper surface of the lower interlayer insulating layer and a lower surface of the active pattern,
wherein the lower via is in contact with the side walls of the active cut, and
wherein a lower surface of the lower via is coplanar with a lower surface of the active cut in the vertical direction.

16. The semiconductor device of claim 13, wherein the third gate spacer is in contact with the side walls of the active cut.

17. The semiconductor device of claim 13, further comprising:
a third gate electrode between the side walls of the active cut and the third gate spacer in the first horizontal direction.

18. The semiconductor device of claim 13, wherein the capping layer includes
a first sub capping layer that is in contact with the upper surface of the first gate electrode and the upper surface of the first gate spacer; and
a second sub capping layer that is in contact with the upper surface of the third gate spacer and the side walls of the active cut,
wherein the second sub capping layer is spaced apart from the first sub capping layer in the first horizontal direction,
wherein the active cut extends into the second sub capping layer in the vertical direction, and
wherein the uppermost surface of the active cut is farther than an upper surface of the second sub capping layer from the upper surface of the lower interlayer insulating layer in the vertical direction.

19. The semiconductor device of claim 13, further comprising:
an insulating liner layer between the active cut and the active pattern.

20. A semiconductor device comprising:
a lower interlayer insulating layer;
an active pattern extending on an upper surface of the lower interlayer insulating layer, wherein the active pattern extends in a first horizontal direction that is parallel with the upper surface of the lower interlayer insulating layer, and wherein the active pattern is spaced apart from the upper surface of the lower interlayer insulating layer in a vertical direction that is perpendicular to the upper surface of the lower interlayer insulating layer;
a first plurality of nanosheets that are spaced apart from each other in the vertical direction on the active pattern;
a second plurality of nanosheets that are spaced apart from each other in the vertical direction on the active pattern, wherein the second plurality of nanosheets are spaced apart from the first plurality of nanosheets in the first horizontal direction;
a third plurality of nanosheets that are spaced apart from each other in the vertical direction on the active pattern, wherein the third plurality of nanosheets are between the first plurality of nanosheets and the second plurality of nanosheets in the first horizontal direction;
a first gate electrode on the active pattern, wherein the first gate electrode extends in a second horizontal direction that is parallel with the upper surface of the lower interlayer insulating layer and intersects the first horizontal direction, and wherein the first gate electrode extends around the first plurality of nanosheets;
a second gate electrode on the active pattern, wherein the second gate electrode extends in the second horizontal direction and is spaced apart from the first gate electrode in the first horizontal direction, and wherein the second gate electrode extends around the second plurality of nanosheets;
a lower separation layer on the upper surface of the lower interlayer insulating layer, wherein the lower separation layer extends into the active pattern in the vertical direction, and wherein the lower separation layer overlaps the first gate electrode in the vertical direction;
an active cut on the upper surface of the lower interlayer insulating layer, wherein the active cut extends in the second horizontal direction, wherein the active cut is between the first gate electrode and the second gate electrode in the first horizontal direction, wherein the active cut is spaced apart from the lower separation layer in the first horizontal direction, and wherein the active cut extends into the active pattern and the third plurality of nanosheets in the vertical direction;
a lower via between the upper surface of the lower interlayer insulating layer and a lower surface of the active pattern, wherein the lower via is in contact with side walls the active cut and side walls of the lower separation layer;
a source/drain region on the active pattern, wherein the source/drain region is between the first plurality of nanosheets and the second plurality of nanosheets in the first horizontal direction;
a lower source/drain contact on an upper surface of the lower via, wherein the lower source/drain contact extends into the active pattern, and wherein the lower source/drain contact is electrically connected to the source/drain region;
a first gate spacer on side walls of the first gate electrode;
a second gate spacer on side walls of the second gate electrode;
a third gate spacer on the side walls of the active cut; and
a capping layer that is in contact with upper surfaces of the first gate electrode and the second gate electrode and upper surfaces of the first gate spacer, the second gate spacer, and the third gate spacer,
wherein the active cut extends into the capping layer in the vertical direction,
wherein an uppermost surface of the active cut is farther than an upper surface of the capping layer from the upper surface of the lower interlayer insulating layer in the vertical direction, and
wherein at least a part of the active pattern is between the lower source/drain contact and the active cut in the first horizontal direction.
